(19) United States
(12) Patent Application Publication
(10) Pub. No.: US 2026/0179693 A1
(43) Pub. Date: Jun. 25, 2026

(54) VOLTAGE GENERATION CIRCUIT AND SEMICONDUCTOR MEMORY DEVICE

(71) Applicant: Kioxia Corporation, Tokyo (JP)

(72) Inventor: Hiroshi YOSHIHARA, Fujisawa Kanagawa (JP)

(21) Appl. No.: 19/310,861

(22) Filed: Aug. 26, 2025

(30) Foreign Application Priority Data
Dec. 20, 2024 (JP) 2024-225179

(51) Int. Cl. G11C 16/30; G11C 16/04

(52) U.S. Cl. CPC G11C 16/30; G11C 16/0483

(57) ABSTRACT

A voltage generation circuit includes a variable resistor connected to a voltage output line, a reference resistor connected in series to a low-voltage side of the variable resistor, a detection circuit, and a voltage adjustment circuit. The detection circuit detects a voltage at a first connection point between the variable resistor and the reference resistor. The voltage adjustment circuit adjusts a voltage at the voltage output line, based on the voltage detected by the detection circuit. The variable resistor includes a plurality of resistance elements that are connected in series between the voltage output line and the first connection point, a plurality of switching elements that are respectively provided between second connection points, each of which is located between a different adjacent pair of the resistance elements, and the first connection point, and a diode that is connected in parallel to at least one of the plurality of resistance elements.

### CROSS-REFERENCE TO RELATED APPLICATION(S)

This application is based upon and claims the benefit of priority from Japanese Patent Application No. 2024-225179, filed Dec. 20, 2024, the entire contents of which are incorporated herein by reference.

### FIELD

Embodiments described herein relate generally to a voltage generation circuit and a semiconductor memory device.

### BACKGROUND

Voltage generation circuits are used in semiconductor memory devices such as NAND flash memories.

### BRIEF DESCRIPTION OF THE DRAWINGS

FIG. 1 is a block diagram showing a schematic configuration of a memory system according to a first embodiment.

FIG. 2 is a block diagram showing a schematic configuration of a semiconductor memory device according to the first embodiment.

FIG. 3 is a circuit diagram showing a configuration of the semiconductor memory device according to the first embodiment.

FIG. 4 is a cross-sectional view showing a cross-sectional structure of the semiconductor memory device according to the first embodiment.

FIG. 5 is a diagram showing an example of a threshold voltage distribution of a memory cell transistor according to the first embodiment.

FIG. 6 is a diagram showing voltage changes in each wiring during a program operation of the memory cell transistor according to the first embodiment.

FIG. 7 is a diagram showing voltage changes in each wiring during a read operation of the memory cell transistor according to the first embodiment.

FIG. 8 is a diagram showing voltage changes in word lines during a write operation in the first embodiment.

FIG. 9 is a diagram showing a relationship between a loop count and a verification operation during the write operation in the first embodiment.

FIG. 10 is a diagram showing a relationship between a loop count and a program operation during the write operation in the first embodiment.

FIG. 11 is a block diagram showing a schematic configuration of a row decoder according to the first embodiment.

FIG. 12 is a block diagram showing a schematic configuration of a voltage supply circuit according to the first embodiment.

FIG. 13 is a circuit diagram showing a configuration of a first voltage generation unit according to the first embodiment.

FIG. 14 is a circuit diagram showing a configuration of a charge pump circuit according to the first embodiment.

FIG. 15 is a circuit diagram showing a configuration of a detection circuit according to the first embodiment.

FIG. 16 is a circuit diagram showing an example of the operation of the detection circuit according to the first embodiment.

FIG. 17 is a circuit diagram showing a configuration of a detection circuit according to a reference example.

FIG. 18 is a circuit diagram showing a configuration of a detection circuit according to a first modification example of the first embodiment.

FIG. 19 is a circuit diagram showing a configuration of a detection circuit according to a second modification example of the first embodiment.

FIG. 20 is a circuit diagram showing a configuration of a detection circuit according to a third modification example of the first embodiment.

FIG. 21 is a circuit diagram showing a configuration of a detection circuit according to a second embodiment.

FIGS. 22-25 are each a circuit diagram showing a configuration of a detection circuit according to another embodiment.

FIG. 26 is a cross-sectional view showing a cross-sectional structure of a semiconductor memory device according to another embodiment.

### DETAILED DESCRIPTION

Embodiments provide a voltage generation circuit and a semiconductor memory device which are capable of improving breakdown voltage performance.

In general, according to one embodiment, a voltage generation circuit includes a variable resistor, a reference resistor, a detection circuit, and a voltage adjustment circuit. The variable resistor is connected to a voltage output line. The reference resistor is connected in series to a low-voltage side of the variable resistor. The detection circuit detects a voltage at a first connection point between the variable resistor and the reference resistor. The voltage adjustment circuit adjusts a voltage at the voltage output line, based on the voltage detected by the detection circuit. The variable resistor includes a plurality of resistance elements that are connected in series between the voltage output line and the first connection point, a plurality of switching elements that are respectively provided between second connection points, each of which is located between a different adjacent pair of the resistance elements, and the first connection point, and a diode that is connected in parallel to at least one of the plurality of resistance elements.

Hereinafter, embodiments will be described with reference to the drawings. In order to facilitate understanding of the description, the same components in each drawing are denoted by the same reference numerals as much as possible, and repeated description will be avoided.

### 1 First Embodiment

A semiconductor memory device according to a first embodiment will be described. The semiconductor memory device according to this embodiment is a non-volatile memory device configured as a NAND flash memory.

### 1.1 Configuration of Memory System

First, a configuration of a memory system according to this embodiment will be described.

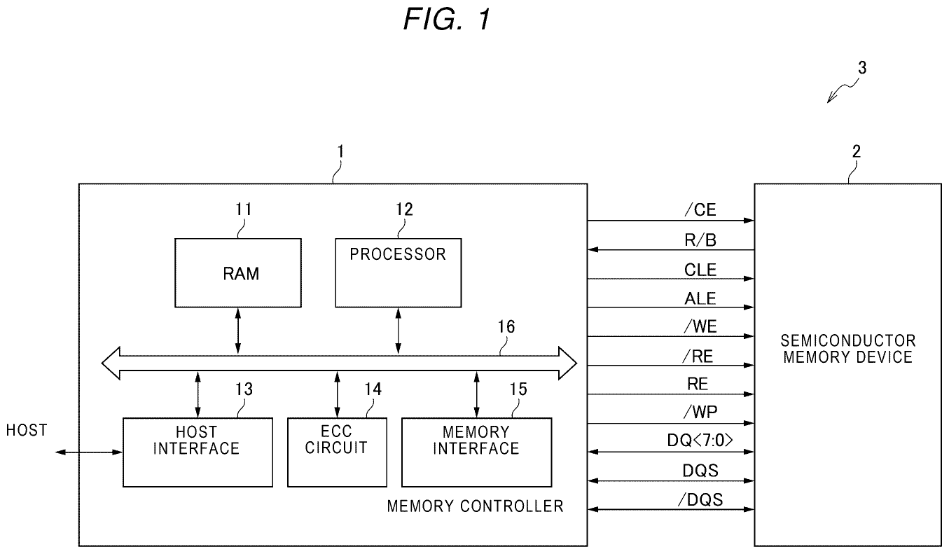

As shown in FIG. 1, a memory system 3 according to this embodiment includes a memory controller 1 and a semiconductor memory device 2. The memory system 3 can be connected to a host. The host is, for example, electronic equipment such as a personal computer or a portable terminal.

The memory controller 1 controls writing of data to the semiconductor memory device 2 in response to a write request from the host. The memory controller 1 also controls reading of data from the semiconductor memory device 2 in response to a read request from the host.

Between the memory controller 1 and the semiconductor memory device 2, signals of a chip enable signal /CE, a ready/busy signal R/B, a command latch enable signal CLE, an address latch enable signal ALE, a write enable signal /WE, read enable signals /RE and RE, a write protect signal /WP, a signal DQ<7:0>, and data strobe signals DQS and /DQS are transmitted and received.

The chip enable signal /CE is transmitted from the memory controller 1 to the semiconductor memory device 2. The chip enable signal /CE is a signal for enabling the semiconductor memory device 2. The ready/busy signal R/B is transmitted from the semiconductor memory device 2 to the memory controller 1. The ready/busy signal R/B is a signal for indicating whether the semiconductor memory device 2 is in a ready state or a busy state. The “ready state” is, for example, a state in which a command can be received from the outside. A “busy state” is, for example, a state in which a command cannot be received from the outside.

The command latch enable signal CLE is transmitted from the memory controller 1 to the semiconductor memory device 2. The command latch enable signal CLE is a signal indicating that the signal DQ<7:0>is a command. The address latch enable signal ALE is transmitted from the memory controller 1 to the semiconductor memory device 2. The address latch enable signal ALE is a signal indicating that the signal DQ<7:0>is an address. The write enable signal /WE is transmitted from the memory controller 1 to the semiconductor memory device 2. The write enable signal /WE is a signal asserted by the memory controller 1 every time it transmits a command, an address, and data to the semiconductor memory device. The memory controller 1 instructs the semiconductor memory device 2 to capture the signal DQ<7:0>while the write enable signal /WE is at a “L (Low)” level.

The read enable signal /RE is transmitted from the memory controller 1 to the semiconductor memory device 2. The signal RE is a complementary signal of the signal /RE. The read enable signals /RE and RE are signals for the memory controller 1 to read data from the semiconductor memory device 2. The read enable signals /RE and RE are used to control the operation timing of the semiconductor memory device 2 when outputting the signal DQ<7:0>, for example. The signal DQ<7:0>contains data transmitted and received between the semiconductor memory device 2 and the memory controller 1, and includes commands, addresses, and data. The data strobe signal DQS is a timing control signal transmitted and received between the semiconductor memory device 2 and the memory controller 1 in response to the signal DQ<7:0>. The signal /DQS is a complementary signal of the signal DQS. The data strobe signals DQS and /DQS are signals for controlling the timing of input and output of the signal DQ<7:0>.

The memory controller 1 includes a RAM 11, a processor 12, a host interface 13, an ECC circuit 14, and a memory interface 15. These are connected to each other via an internal bus 16.

The host interface 13 outputs requests, user data (write data), and the like received from the host to the internal bus 16. The host interface 13 also transmits user data read from the semiconductor memory device 2, responses from the processor 12, and the like to the host.

The memory interface 15 controls a process of writing user data, and the like to the semiconductor memory device 2 and a process of reading out data from the semiconductor memory device 2 based on instructions from the processor 12.

The processor 12 comprehensively controls the memory controller 1. The processor 12 may be a CPU, an MPU, or the like. When the processor 12 receives a request from the host via the host interface 13, the processor 12 performs control according to the request. For example, the processor 12 instructs the memory interface 15 to write user data and parity to the semiconductor memory device 2 in response to the request from the host. The processor 12 also instructs the memory interface 15 to read user data and parity from the semiconductor memory device 2 in response to the request from the host.

The processor 12 determines a storage area (memory area) on the semiconductor memory device 2 for user data accumulated in the RAM 11. The user data is stored in the RAM 11 via the internal bus 16. The processor 12 determines the memory area for data in units of pages (page data), which are the writing units. User data stored in one page of the semiconductor memory device 2 is also referred to as “unit data” below. The unit data is generally encoded and stored in the semiconductor memory device 2 as a code word. In this embodiment, encoding is not essential. The memory controller 1 may store the unit data in the semiconductor memory device 2 without encoding it, but a configuration in which encoding is performed is shown in FIG. 1 as an example.

The processor 12 determines a memory area of the semiconductor memory device 2 to which each unit data is to be written. A physical address is assigned to the memory area of the semiconductor memory device 2. The processor 12 manages the memory area to which unit data is to be written, by using the physical address. The processor 12 instructs the memory interface 15 to write user data to the semiconductor memory device 2 by designating the determined memory area (physical address). The processor 12 manages correspondence between a logical address of user data (a logical address managed by the host) and a physical address. When the processor 12 receives a read request including a logical address from the host, the processor 12 specifies a physical address that corresponds to the logical address, and instructs the memory interface 15 to read the user data by designating the physical address.

The ECC circuit 14 generates code words by encoding user data stored in the RAM 11. The ECC circuit 14 also decodes code words read from the semiconductor memory device 2.

The RAM 11 temporarily stores user data received from the host before storing it in the semiconductor memory device 2, and temporarily stores data read from the semiconductor memory device 2 before transmitting it to the host. The RAM 11 is, for example, a general-purpose memory such as an SRAM or a DRAM.

FIG. 1 shows an example of a configuration in which the memory controller 1 includes the ECC circuit 14 and the memory interface 15. However, the ECC circuit 14 may be built into the memory interface 15. The ECC circuit 14 may also be built into the semiconductor memory device 2. A specific configuration and arrangement of the elements shown in FIG. 1 are not particularly limited.

When a write request is received from the host, the memory system 3 in FIG. 1 operates as follows. The processor 12 temporarily stores data to be written in the RAM 11. The processor 12 reads out the data stored in the RAM 11 and inputs it to the ECC circuit 14. The ECC circuit 14 encodes the input data and inputs a code word to the memory interface 15. The memory interface 15 writes the input code word to the semiconductor memory device 2.

When a read request is received from the host, the memory system 3 in FIG. 1 operates as follows. The memory interface 15 inputs the code word read from the semiconductor memory device 2 to the ECC circuit 14. The ECC circuit 14 decodes the input code word and stores the decoded data in the RAM 11. The processor 12 transmits the data stored in the RAM 11 to the host via the host interface 13.

### 1.2 Schematic Configuration of Semiconductor Memory Device

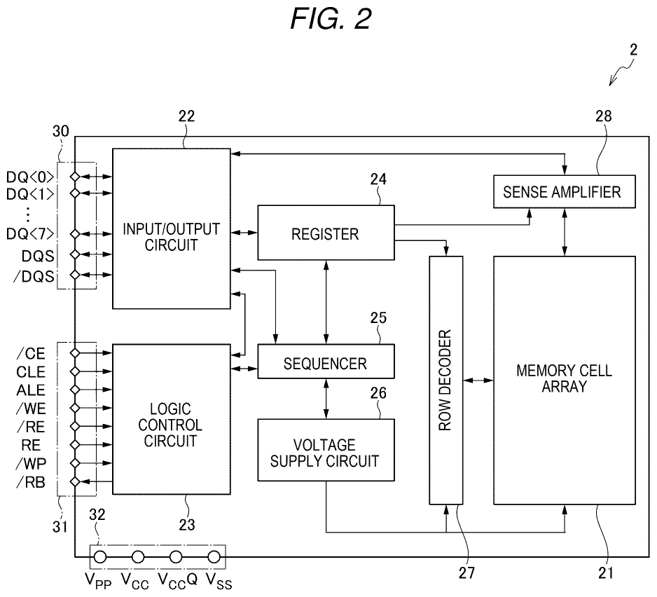

As shown in FIG. 2, the semiconductor memory device 2 includes a memory cell array 21, an input/output circuit 22, a logic control circuit 23, a register 24, a sequencer 25, a voltage supply circuit 26, a row decoder 27, a sense amplifier 28, an input/output pad group 30, a logic control pad group 31, and a power input terminal group 32.

The memory cell array 21 is a part that stores data. The memory cell array 21 includes a plurality of memory cell transistors associated with a plurality of bit lines and a plurality of word lines.

The input/output circuit 22 transmits and receives the signal DQ<7:0>and the data strobe signals DQS and /DQS to and from the memory controller 1. The input/output circuit 22 also transfers the command and address in the signal DQ<7:0>to the register 24. Furthermore, the input/output circuit 22 transmits and receives write data and read data to and from the sense amplifier 28.

The logic control circuit 23 receives the chip enable signal /CE, the command latch enable signal CLE, the address latch enable signal ALE, the write enable signal /WE, the read enable signals RE and /RE, and the write protect signal /WP from the memory controller 1. The logic control circuit 23 also transfers the ready/busy signal /RB to the memory controller 1 to notify the outside of the state of the semiconductor memory device 2.

The register 24 temporarily stores various data. For example, the register 24 stores commands for instructing write, read, and erase operations. These commands are input from the memory controller 1 to the input/output circuit 22, and then transferred from the input/output circuit 22 to the register 24 and stored. The register 24 also stores addresses corresponding to the above-mentioned commands. These addresses are input to the input/output circuit 22 from the memory controller 1, and then transferred from the input/output circuit 22 to the register 24 and stored. Furthermore, the register 24 also stores status information indicating the operating state of the semiconductor memory device 2. The status information is updated by the sequencer 25 each time in accordance with the operating state of the memory cell array 21 and the like. In response to a request from the memory controller 1, the status information is output from the input/output circuit 22 to the memory controller 1 as a state signal.

The sequencer 25 controls the operations of each part, including the memory cell array 21, based on a control signal input from the memory controller 1 to the input/output circuit 22 and the logic control circuit 23. In this embodiment, the sequencer 25 is an example of a control unit or a control circuit.

The voltage supply circuit 26 is a part that generates voltages required for a write operation, a read operation, and an erase operation of data in the memory cell array 21. These voltages include, for example, voltages applied to the plurality of word lines and the plurality of bit lines of the memory cell array 21. The operation of the voltage supply circuit 26 is controlled by the sequencer 25.

The row decoder 27 is a circuit configured with a switch group for applying voltages to each of the plurality of word lines of the memory cell array 21. The row decoder 27 receives a block address and a row address from the register 24, selects a block based on the block address, and selects a word line based on the row address. The row decoder 27 switches the open/close state of the switch group so that a voltage from the voltage supply circuit 26 is applied to the selected word line. The operation of the row decoder 27 is controlled by the sequencer 25.

The sense amplifier 28 is a circuit that adjusts a voltage applied to the bit line of the memory cell array 21 and reads the voltage of the bit line and converts it into data. When reading data, the sense amplifier 28 determines the data stored in the memory cell transistor of the memory cell array 21 using the bit line and transfers the read data to the input/output circuit 22. When writing data, the sense amplifier 28 stores the write data in the memory cell transistor using the bit line. The operation of the sense amplifier 28 is controlled by the sequencer 25.

The input/output pad group 30 is a part that is provided with a plurality of terminals (pads) for transmitting and receiving signals between the memory controller 1 and the input/output circuit 22. Each of the terminals is provided individually to correspond to each of the signal DQ<7:0>and the data strobe signals DQS and /DQS.

The logic control pad group 31 is a part that is provided with a plurality of terminals for transmitting and receiving signals between the memory controller 1 and the logic control circuit 23. Each of the terminals is provided individually to correspond to the chip enable signal /CE, the command latch enable signal CLE, the address latch enable signal ALE, the write enable signal /WE, the read enable signals RE and /RE, the write protect signal /WP, and the ready busy signal /RB.

The power input terminal group 32 is a part that is provided with a plurality of terminals for receiving the application of voltages necessary for the operation of the semiconductor memory device 2. The voltages applied to each of the terminals include power supply voltages Vcc, VccQ, and Vpp, and a ground voltage Vss. The power supply voltage Vcc is a circuit power supply voltage given from the outside as an operating power supply, and is, for example, a voltage of approximately 2.5 V. The power supply voltage Vcc is a voltage for generating a voltage Vdd, which is, for example, the internal power supply voltage of the semiconductor memory device 2. The power supply voltage Vdd is, for example, a voltage of approximately 1.5 V. The power supply voltage VccQ is a power supply voltage lower than the power supply voltage Vcc, and is, for example, a voltage of 1.2 V. The power supply voltage VccQ is an input/output power supply voltage used when transmitting and receiving signals between the memory controller 1 and the semiconductor memory device 2. The power supply voltage Vpp is a power supply voltage higher than the power supply voltage Vcc, and is, for example, a voltage of 12 V.

### 1.3 Circuit Configuration of Memory Cell Array

Next, the configuration of the memory cell array 21 will be described.

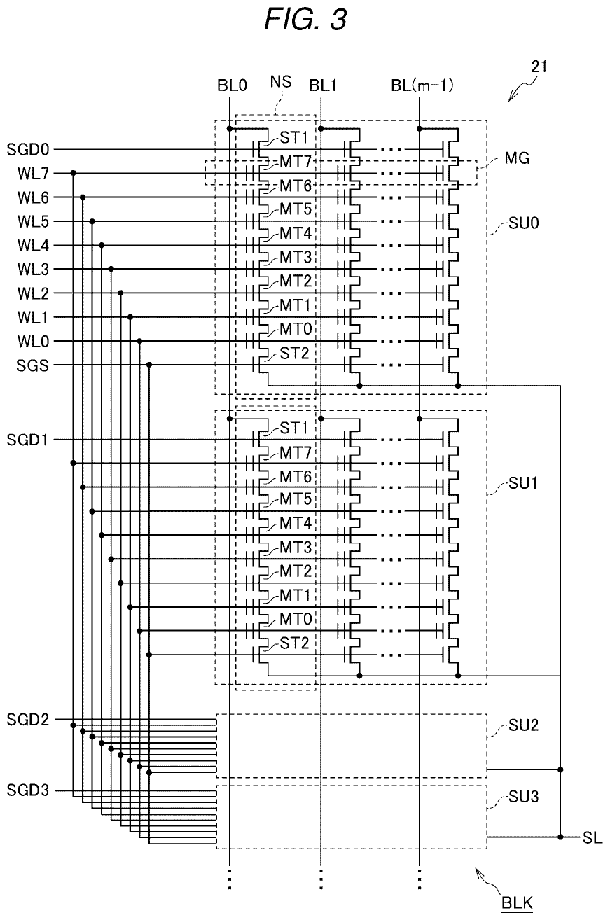

As shown in FIG. 3, the memory cell array 21 is configured with a plurality of blocks BLK. In FIG. 3, only one of the plurality of blocks BLK is shown. The configuration of the other blocks BLK in the memory cell array 21 is also similar to that shown in FIG. 3.

As shown in FIG. 3, the block BLK includes, for example, four string units SU (SU0 to SU3). In addition, each string unit SU includes a plurality of NAND strings NS. Each NAND string NS includes, for example, eight memory cell transistors MT (MT0 to MT7) and select transistors ST1 and ST2.

The memory cell transistor MT is connected in series between the select transistor ST1 and the select transistor ST2. The memory cell transistor MT7 on one end side is connected to a source of the select transistor ST1, and the memory cell transistor MT0 on the other end side is connected to a drain of the select transistor ST2.

Gates of the select transistors ST1 of the string units SU0 to SU3 are connected in common to select gate lines SGD0 to SGD3, respectively. Gates of the select transistors ST2 are connected in common to the same select gate line SGS between a plurality of string units SU in the same block BLK. Gates of the memory cell transistors MT0 to MT7 in the same block BLK are connected in common to word lines WL0 to WL7, respectively. In other words, the word lines WL0 to WL7 and a select gate line SGS are common to a plurality of string units SU0 to SU3 in the same block BLK, whereas the select gate line SGD is provided individually for each of the string units SU0 to SU3 even in the same block BLK.

The memory cell array 21 is provided with m bit lines BL (BL0, BL1, ..., BL(m−1)). Here, “m” is an integer corresponding to the number of NAND strings NS in one string unit SU. A drain of a select transistor ST1 of each of the NAND strings NS is connected to the corresponding bit line BL. A source of a select transistor ST2 of each of the NAND strings NS is connected to a source line SL. The source line SL is common to sources of a plurality of select transistors ST2 of the block BLK.

Data stored in a plurality of memory cell transistors MT in the same block BLK are erased all at once. On the other hand, data are read and written all at once to a plurality of memory cell transistors MT connected to one word line WL and belonging to one string unit SU.

Each of the memory cell transistors MT can store three bits of data that include an upper bit, a middle bit, and a lower bit. In other words, the semiconductor memory device 2 according to this embodiment implements a TLC (triple-level cell) method, which allows 3-bit data to be stored in each memory cell transistor MT, as a method of writing data to the memory cell transistor MT. Instead of such a configuration, a method of writing data to the memory cell transistor MT may implement an MLC (multi-level cell)method in which 2-bit data is stored in each memory cell transistor MT, or an SLC (single-level cell) method in which 1-bit data is stored in each memory cell transistor MT.

It is noted that, in the following description, a set of 1-bit data stored in a plurality of memory cell transistors MT connected to one word line WL and belonging to one string unit SU is referred to as a “page”. In FIG. 3, one of the sets that has a plurality of memory cell transistors MT as described above is given a symbol “MG”.

When three bits of data are stored in each memory cell transistor MT as in this embodiment, a set of a plurality of memory cell transistors MT connected to a common word line WL in one string unit SU can store 3 pages of data.

### 1.4 Cross-sectional Structure of Semiconductor Memory Device

Next, the memory cell array 21 and its surrounding structure will be described.

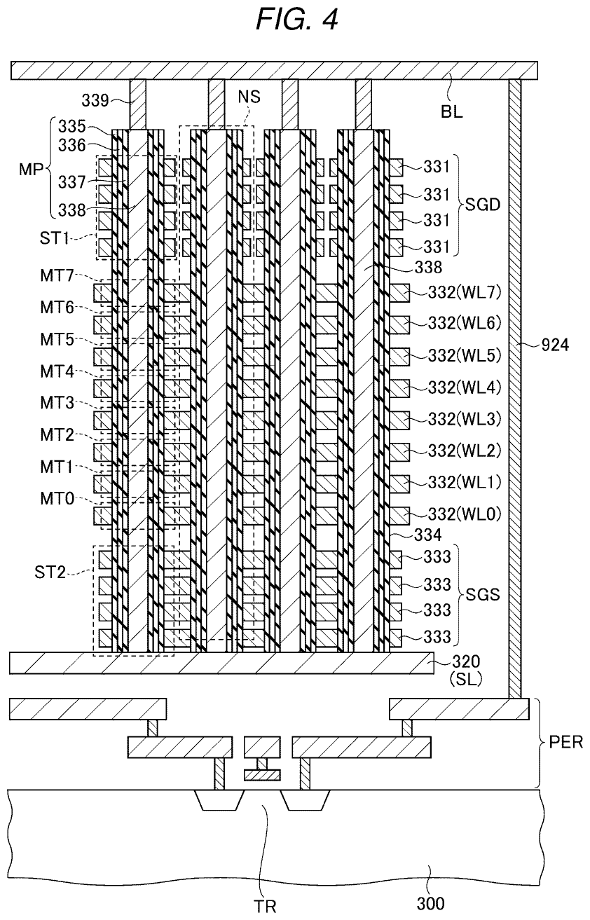

As shown in FIG. 4, in the memory cell array 21, a plurality of NAND strings NS are formed on a conductive layer 320. The conductive layer 320 is also referred to as a buried source line (BSL) and corresponds to the source line SL shown in FIG. 3.

Above the conductive layer 320, a plurality of wiring layers 333 functioning as select gate lines SGS, a plurality of wiring layers 332 functioning as word lines WL, and a plurality of wiring layers 331 functioning as select gate lines SGD are stacked. An insulating layer (not shown) is disposed between the stacked wiring layers 333, 332, and 331.

A plurality of memory holes 334 are formed in the memory cell array 21. The memory holes 334 are holes that vertically penetrate the wiring layers 333, 332, and 331 and the insulating layers (not shown) therebetween, and reach the conductive layer 320. A block insulating film 335, a charge storage layer 336, and a gate insulating film 337 are formed in this order on the side surface of the memory holes 334, and a conductive pillar 338 is buried in the memory holes 334. The conductive pillar 338 is formed of, for example, polysilicon, and functions as a region in which a channel is formed during the operation of the memory cell transistor MT and the select transistors ST1 and ST2 in the NAND string NS. In the following, a pillar-shaped body including the block insulating film 335, the charge storage layer 336, the gate insulating film 337, and the conductive pillar 338 in the memory hole 334 will also be referred to as a memory pillar MP.

In the memory pillar MP, each portion that intersects each of the stacked wiring layers 333, 332, and 331 functions as a transistor. Among these plurality of transistors, a transistor located at the portion intersecting the wiring layer 331 functions as a select transistor ST1. Of the plurality of transistors, the one at the portion that intersects with wiring layer 332 functions as a memory cell transistor MT (MT0 to MT7). Of the plurality of transistors, the one at the portion that intersects with wiring layer 333 functions as a select transistor ST2. With such a configuration, the memory pillar MP functions as a NAND string NS shown in FIG. 3. The conductive pillar 338 located on the inner side of the memory pillar MP is a portion that functions as a channel for the memory cell transistor MT and the select transistors ST1 and ST2.

Above the conductive pillar 338, a wiring layer that functions as a bit line BL is formed. At an upper end of the conductive pillar 338, a contact plug 339 that connects the conductive pillar 338 to the bit line BL is formed.

A plurality of configurations similar to the configuration shown in FIG. 4 are arranged in the depth direction of the paper in FIG. 4. A single string unit SU is formed by a set of a plurality of NAND strings NS lined up in a row in the depth direction of the drawing sheet containing FIG. 4.

In the semiconductor memory device 2 according to this embodiment, a peripheral circuit PER is provided below the memory cell array 21, that is, between the memory cell array 21 and a semiconductor substrate 300. The peripheral circuit PER is a circuit provided to implement a write operation, a read operation, and an erase operation of data in the memory cell array 21. The sense amplifier 28, the row decoder 27, the voltage supply circuit 26, and the like shown in FIG. 2 are parts of the peripheral circuit PER. The peripheral circuit PER includes various transistors, an RC circuit, and the like. In the example shown in FIG. 4, the transistor TR formed on the semiconductor substrate 300 and the bit line BL on the upper side of the memory cell array 21 are electrically connected to each other via a contact 924.

### 1.5 Threshold Voltage Distribution of Memory Cell Transistor

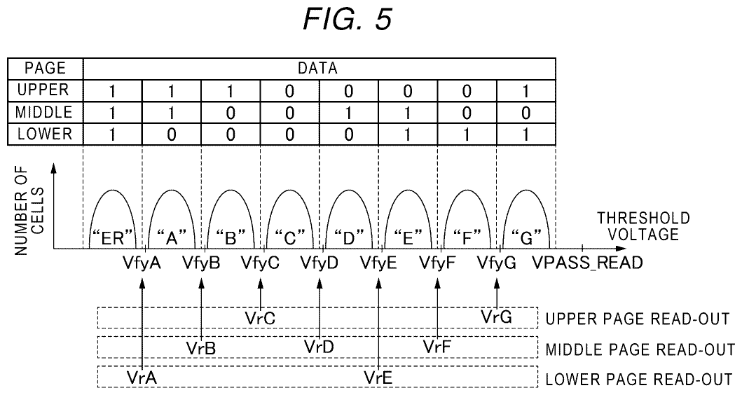

Next, a threshold voltage distribution of the memory cell transistor MT will be described. FIG. 5 is a diagram schematically showing a threshold voltage distribution of the memory cell transistor MT, and the like. A diagram in the middle part of FIG. 5 shows a correspondence relationship between a threshold voltage of the memory cell transistor MT (horizontal axis) and the number of memory cell transistors MT (vertical axis).

When a TLC method is employed as in this embodiment, the plurality of memory cell transistors MT form eight threshold voltage distributions as shown in the middle part of FIG. 5. These eight threshold voltage distributions (write levels) are referred to as an “ER” state, an “A” state, a “B” state, a “C” state, a “D” state, an “E” state, an “F” state, and a “G” state in ascending order of a threshold voltage.

A table in the upper part of FIG. 5 shows an example of data assigned to each of the above-mentioned threshold voltage levels. As shown in the table, each level is assigned, for example, different 3-bit data as shown below.
“ER” state: “111” (“lower bit/middle bit/higher bit”)
“A” state: “011”
“B” state: “001”
“C” state: “000”
“D” state: “010”
“E” state: “110”
“F” state: “100”
“G” state: “101”

In this manner, a threshold voltage of the memory cell transistor MT in this embodiment can take one of eight preset candidate levels, and data is assigned to correspond to each of the candidate levels as described above.

A verification voltage used in a write operation is set between a pair of threshold voltage distributions adjacent to each other. Specifically, verification voltages VfyA, VfyB, VfyC, VfyD, VfyE, VfyF, and VfyG are set to correspond to a plurality of levels, respectively.

The verification voltage VfyA is set between a maximum threshold voltage at the “ER” state and a minimum threshold voltage at the “A” state. When the verification voltage VfyA is applied to the word line WL, among the memory cell transistors MT connected to the word line WL, the memory cell transistors MT of which the threshold voltage is included in the “ER” state are set to be in an on state, and the memory cell transistors MT of which the threshold voltage is included in a threshold voltage distribution equal to or higher than the “A” state are set to be in an off state.

The other verification voltages VfyB, VfyC, VfyD, VfyE, VfyF, and VfyG are set in the same manner as the verification voltage VfyA described above. The verification voltage VfyB is set between the “A” state and the “B” state, the verification voltage VfyC is set between the “B” state and the “C” state, the verification voltage VfyD is set between the “C” state and the “D” state, the verification voltage VfyE is set between the “D” state and the “E” state, the verification voltage VfyF is set between the “E” state and the “F” state, and the verification voltage VfyG is set between the “F” state and the “G” state.

For example, the verification voltage VfyA may be set to 0.8 V, the verification voltage VfyB may be set to 1.6 V, the verification voltage VfyC may be set to 2.4 V, the verification voltage VfyD may be set to 3.1 V, the verification voltage VfyE may be set to 3.8 V, the verification voltage VfyF may be set to 4.6 V, and the verification voltage VfyG may be set to 5.6 V. However, the present disclosure is not limited thereto, the verification voltages VfyA, VfyB, VfyC, VfyD, VfyE, VfyF, and VfyG may be appropriately set in a stepwise manner, for example, within the range of 0 V to 7.0 V.

In addition, a read voltage used in a read operation is set between adjacent threshold voltage distributions. The “read voltage” is a voltage applied to a word line WL connected to a memory cell transistor MT to be read during a read operation, that is, to a selected word line. In the read operation, data is determined based on a result of determining whether the threshold voltage of the memory cell transistor MT to be read is higher than the applied read voltage.

As schematically shown in the diagram in the lower part of FIG. 5, specifically, a read voltage VrA for determining whether the threshold voltage of the memory cell transistor MT is included in the “ER” state or a level equal to or higher than the “A” state is set between a maximum threshold voltage at the “ER” state and a minimum threshold voltage at the “A” state.

The other read voltages VrB, VrC, VrD, VrE, VrF, and VrG are set in the same manner as the read voltage VrA described above. The read voltage VrB is set between the “A” state and the “B” state, the read voltage VrC is set between the “B” state and the “C” state, the read voltage VrD is set between the “C” state and the “D” state, the read voltage VrE is set between the “D” state and the “E” state, the read voltage VrF is set between the “E” state and the “F” state, and the read voltage VrG is set between the “F” state and the “G” state.

A read pass voltage VPASS_READ is set to a voltage higher than the maximum threshold voltage of the highest threshold voltage distribution (for example, the “G” state). The memory cell transistor MT having a gate to which the read pass voltage VPASS_READ is applied is set to be in an on state regardless of data stored therein.

It is noted that the verification voltages VfyA, VfyB, VfyC, VfyD, VfyE, VfyF, and VfyG are set to voltages higher than the read voltages VrA, VrB, VrC, VrD, VrE, VrF, and VrG, respectively. In other words, the verification voltages VfyA, VfyB, VfyC, VfyD, VfyE, VfyF, and VfyG are set to the vicinities of the lower ends of the threshold voltage distributions of the “A” state, “B” state, “C” state, “D” state, “E” state, “F” state, and “G” state, respectively.

When the above-mentioned data allocation is applied, one page data of lower bits (lower page data) in a read operation can be determined by a read result using the read voltages VrA and VrE. One page data of middle bits (middle page data) can be determined by a read result using the read voltages VrB, VrD, and VrF. One page data of upper bits (upper page data) can be determined by a read result using the read voltages VrC and VrG. In this manner, since the lower page data, middle page data, and upper page data are respectively determined by two, three, and two read operations, the above-mentioned data allocation is referred to as a “2-3-2 code”.

### 1.6 Voltage Changes in Each Wiring During Write Operation of Semiconductor Memory Device

Next, a write operation of the semiconductor memory device 2 will be described. In the write operation, a program operation and a verification operation are performed. The “program operation” is an operation in which electrons are injected into charge storage layers 336 of some memory cell transistors MT to change the threshold voltages of the memory cell transistors MT. The “verification operation” is an operation in which, after the above-mentioned program operation, data is read to determine and verify whether the threshold voltage of the memory cell transistor MT reaches a target level. The memory cell transistor MT of which the threshold voltage reaches the target level is then write-protected. The “target level” here refers to a specific candidate level that is set as a target level from the above-mentioned eight candidate levels.

In a write operation, the above-mentioned program and verification operations are repeatedly executed. Thereby, the threshold voltage of the memory cell transistor MT rises to the target level.

Among the plurality of word lines WL, a word line WL connected to a memory cell transistor MT which is a target for a write operation (that is, a target of which the threshold voltage is to be changed) is also referred to as a “selected word line” below. In addition, a word line WL connected to a memory cell transistor MT that is not a target for a write operation is also referred to as a “non-selected word line” below. The memory cell transistor MT that is a write target is also referred to as a “selected memory transistor” below.

Among the plurality of string units SU, a string unit SU which is a target for a write operation is also referred to as a “selected string unit” below. In addition, a string unit SU that is not a target for a write operation is also referred to as a “non-selected string unit” below.

A conductive pillar 338 of each NAND string NS in a selected string unit, that is, each channel in the selected string unit, will also be referred to as a “selected channel” below. In addition, the conductive pillar 338 of each NAND string NS in a non-selected string unit, that is, each channel in the non-selected string unit, will also be referred to as a “non-selected channel” below.

Among the plurality of bit lines BL, a bit line BL that is connected to a selected memory transistor is also referred to as a “selected bit line” below. In addition, a bit line BL that is not connected to a selected memory transistor is also referred to as a “non-selected bit line” below.

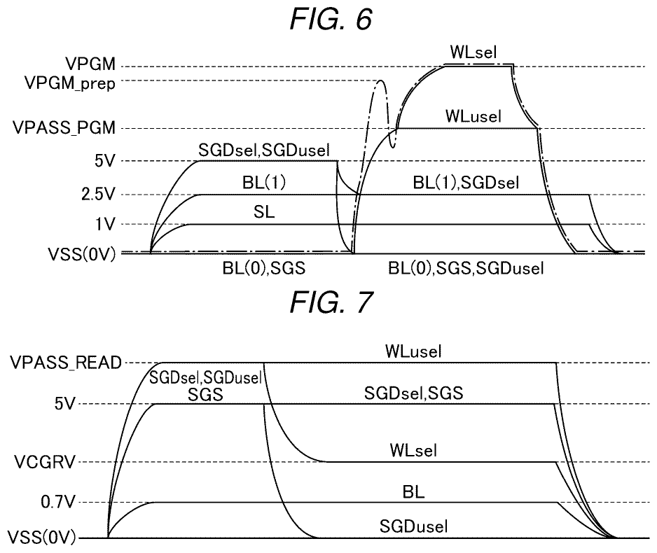

FIG. 6 shows voltage changes in each wiring during a program operation. In the program operation, the sense amplifier 28 changes the voltage of each bit line BL corresponding to program data. For example, a ground voltage Vss (0 V) is applied as an “L” level to a bit line BL connected to a memory cell transistor MT which is to be programmed (of which the threshold voltage is to be increased). For example, 2.5 V is applied as an “H” level to a bit line BL connected to a memory cell transistor MT which is not to be programmed (of which the threshold voltage is to be maintained). The former bit line BL is indicated as “BL(0)” in FIG. 6. The latter bit line BL is indicated as “BL(1)” in FIG. 6.

The row decoder 27 selects one of the blocks BLK as a target for a write operation, and then selects one of the string units SU. More specifically, a voltage of, for example, 5 V is applied to a select gate line SGD (selected select gate line SGDsel) in the selected string unit SU from the voltage supply circuit 26 via the row decoder 27. Thereby, the select transistor ST1 is set to be in an on state. Meanwhile, for example, a voltage Vss is applied to the select gate line SGS from the voltage supply circuit 26 via the row decoder 27. Thereby, the select transistor ST2 is set to be in an off state.

In addition, for example, a voltage of 5 V is applied to a select gate line SGD (non-selected select gate line SGDusel) of a non-selected string unit SU in a selected block BLK from the voltage supply circuit 26 via the row decoder 27. Thereby, the select transistor ST1 is set to be in an on state. It is noted that the select gate lines SGS are connected in common to all string units SU of each block BLK. Thus, the select transistor ST2 is also set to be in an off state in the non-selected string unit SU.

The source line SL is at a higher voltage than the voltage of the select gate line SGS. The voltage is, for example, 1 V.

Thereafter, the voltage of the selected select gate line SGDsel in the selected block BLK is set to, for example, 2.5 V. This voltage is the voltage for turning on the select transistor ST1 corresponding to the bit line BL(0) to which 0 V is applied in the above-mentioned example, but cutting off the select transistor ST1 corresponding to the bit line BL(1) to which 2.5 V is applied. Thereby, in the selected string unit SU, the select transistor ST1 corresponding to the bit line BL(0) is turned on, and the select transistor ST1 corresponding to the bit line BL(1) to which 2.5 V is applied is cut off. Meanwhile, the voltage of the non-selected select gate line SGDusel is set to, for example, a voltage Vss. Thereby, in the non-selected string unit SU, the select transistor ST1 is cut off regardless of the voltage of the bit line BL(0) and the bit line BL(1).

Then, the row decoder 27 selects one of the word lines WL in the selected block BLK as a target for a write operation. For example, a program voltage VPGM is applied to the word line WL, which is a target for a write operation (selected word line WLsel), from the voltage supply circuit 26 via the row decoder 27. Meanwhile, for example, a program pass voltage VPASS_PGM is applied to the other word lines WL (non-selected word lines WLusel) from the voltage supply circuit 26 via the row decoder 27. The program voltage VPGM is a high voltage for injecting electrons into the charge storage layer 336 by a tunneling phenomenon. The program pass voltage VPASS_PGM is a voltage for turning on the memory cell transistor MT connected to the word line WL while being low enough not to change its threshold voltage. VPGM is a voltage higher than VPASS_PGM.

In the NAND string NS corresponding to the bit line BL(0) to be programmed, the select transistor ST1 is set to be in an on state. For this reason, the channel voltage of the memory cell transistor MT connected to the selected word line WLsel is set to 0 V. A voltage difference between a control gate and a channel becomes large, and as a result, electrons are injected into the charge storage layer 336, thereby increasing the threshold voltage of the memory cell transistor MT.

In the NAND string NS corresponding to the bit line BL(1) that is not to be programmed, the select transistor ST1 is set to be in a cut-off state. For this reason, the channel of the memory cell transistor MT connected to the selected word line WLsel is electrically floating, and the channel potential is raised to a level close to the program voltage VPGM due to capacitive coupling with the word line WL and the like. The voltage difference between the control gate and the channel becomes small, and as a result, electrons are not injected into the charge storage layer 336, thereby maintaining the threshold voltage of the memory cell transistor MT. To be exact, the threshold voltage does not fluctuate to an extent that causes a transition to a higher threshold voltage distribution level.

It is noted that a so-called precharge operation of applying a voltage of 5 V to the selected select gate line SGDsel and the non-selected select gate line SGDusel in the initial stage of the program operation may be omitted.

The verification operation performed subsequently to the program operation is the same as a read operation to be described below, and thus the description thereof will be omitted.

### 1.7 Voltage Changes in Each Wiring During Read Operation of Semiconductor Memory Device

Next, a read operation of the semiconductor memory device 2 will be described. FIG. 7 shows voltage changes in each wiring during a read operation. In a read operation, a NAND string NS including a memory cell transistor MT which is a target for the read operation is selected. Alternatively, a string unit SU including a page which is a target for a read operation is selected.

First, for example, 5 V is applied to the selected select gate line SGDsel, the non-selected select gate line SGDusel, and the select gate line SGS from the voltage supply circuit 26 via the row decoder 27. Thereby, the select transistor ST1 and the select transistor ST2 in the selected block BLK are set to be in an on state. In addition, for example, the read pass voltage VPASS_READ is applied to the selected word line WLsel and the non-selected word line WLusel from the voltage supply circuit 26 via the row decoder 27. The read pass voltage VPASS_READ is a voltage capable of turning on the memory cell transistor MT regardless of the threshold voltage of the memory cell transistor MT, while being low enough not to change its threshold voltage. Thereby, a current flows in all NAND strings NS in the selected block BLK, regardless of whether they are selected string units SU or non-selected string units SU.

Next, a read voltage VCGRV such as VrA is applied to the word line WL (selected word line WLsel) connected to the memory cell transistor MT, which is a target for a read operation, from the voltage supply circuit 26 via the row decoder 27. The read pass voltage VPASS_READ is applied to the other word lines (non-selected word lines WLusel).

In addition, for example, a voltage Vss is applied to the non-selected select gate line SGDusel from the voltage supply circuit 26 via the row decoder 27 while maintaining a voltage applied to the selected select gate line SGDsel and the select gate line SGS. Thereby, the select transistor ST1 in the selected string unit SU is maintained in an on state, but the select transistor ST1 in the non-selected string unit SU is set to be in an off state. It is noted that the select transistor ST2 in the selected block BLK is set to be in an on state, regardless of whether it is a selected string unit SU or an non-selected string unit SU.

Thereby, the NAND string NS in the non-selected string unit SU does not form a current path because at least the select transistor ST1 is in an off state. Meanwhile, the NAND string NS in the selected string unit SU forms or does not form a current path depending on a relationship between the read voltage VCGRV applied to the selected word line WLsel and the threshold voltage of the memory cell transistor MT.

The sense amplifier 28 applies a voltage to the bit line BL connected to the selected NAND string NS. In this state, the sense amplifier 28 reads data based on the value of a current flowing through the bit line BL. Specifically, it is determined whether the threshold voltage of the memory cell transistor MT which is a target for a read operation is higher than the read voltage applied to the memory cell transistor MT. It is noted that data reading may be performed based on the value of the current flowing through the bit line BL, or the data reading may be performed based on changes in the voltage of the bit line BL over time. In the latter case, the bit line BL is precharged to a predetermined potential in advance.

The verification operation described above is performed in the same manner as the read operation described above. In the verification operation, a verification voltage such as VfyA is applied to the word line WL connected to the memory cell transistor MT to be verified from the voltage supply circuit 26 via the row decoder 27.

It is noted that an operation of applying a voltage of 5 V to the non-selected select gate line SGDusel and applying the read pass voltage VPASS_READ to the selected word line WLsel in the initial stage of the read operation (verification operation) may be omitted.

### 1.8 Flow of Write Operation of Semiconductor Memory Device

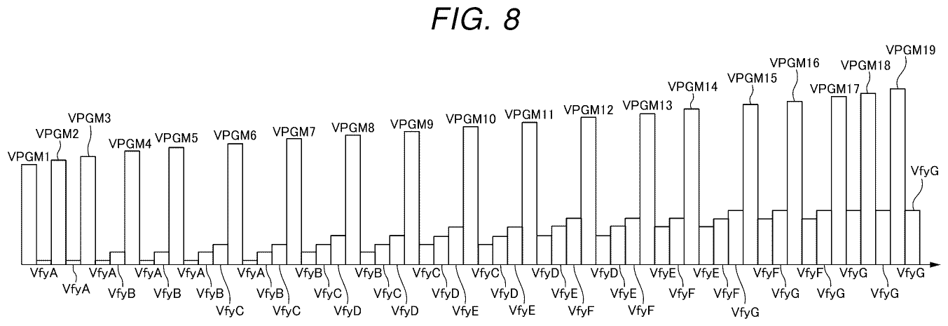

Next, a specific flow of the entire write operation will be described. In a write operation, the above-mentioned program operation and verification operation are repeated until it is confirmed that data is written correctly. FIG. 8 shows an example in which data is written by repeating a combination of a program operation and a verification operation 19 times. Each operation repeated in this manner is also referred to as a “loop” below.

FIG. 8 shows an example of voltage changes in the selected word line WLsel during a write operation. As shown in the drawing, the above-mentioned loop is executed a maximum of 19 times. It is noted that “VPGM 1” shown in FIG. 8 refers to VPGM applied to the selected word line WLsel in a first loop. “VPGM2” refers to VPGM applied to the selected word line WLsel in a second loop. Similarly, VPGM applied to the selected word line WLsel in each loop is written as “VPGM3”, “VPGM4”, . . . , “VPGM19” in FIG. 8. As shown in the drawing, each time a loop is repeated, the value of VPGM is stepped up to become gradually larger.

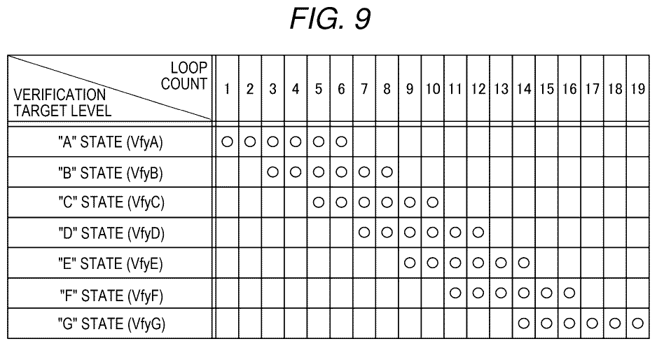

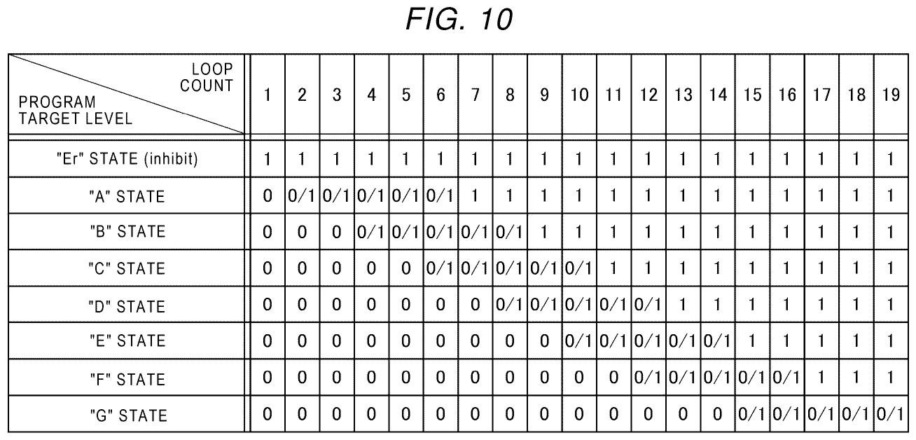

FIG. 9 shows a target level of a verification operation performed in each loop. In addition, FIG. 10 shows a target level of a program operation performed in each loop. It is noted that “1” shown in FIG. 10 means that a write operation is not performed at that level, and “0” means that a write operation is performed at that level. In addition, “0/1” means that a write operation is basically performed at that level, but write operation is not performed when verification is passed in the previous write operation.

As shown in FIGS. 8, 9, and 10, in the first loop in these examples, after VPGM1 is applied to the selected word line WLsel in the program operation, the verification operation is performed only for the “A” state. In other words, during the verification operation, the verification voltage VfyA is applied to the selected word line WLsel, and the verification voltages VfyB to VfyG are not applied.

It is noted that the memory cell transistors MT to be programmed in the first loop are all memory cell transistors MT of which the threshold voltages should eventually be at a level equal to or higher than the “A” state. Meanwhile, the memory cell transistors MT to be verified for the “A” state in the first loop are memory cell transistors MT of which the threshold voltages will eventually be at the “A” state. Memory cell transistors MT of which the threshold voltages will eventually be at a level equal to or higher than the “B” state are excluded from verification targets for the “A” state.

In the second loop, after VPGM2 is applied to the selected word line WLsel, the same program and verification operations as in the first loop are performed. However, among the memory cell transistors MT of which the threshold voltage will eventually be at the “A” state, those that passed verification at the “A” state in the first loop are excluded from targets for program and verification operations in the second loop. In other words, in the second loop, the memory cell transistors MT of which the threshold voltages will eventually be at a level equal to or higher than the “B” state and the memory cell transistors MT that failed verification in the previous loop are targets for the program operation.

In a third loop, after VPGM3 is applied to the selected word line WLsel and the program operation is performed, the verification operation is performed for the “A” state and the “B” state. In other words, during the verification operation, the verification voltages VfyA and VfyB are applied sequentially to the selected word line WLsel, and the verification voltages VfyC to VfyG are not applied.

It is noted that the memory cell transistors MT to be programmed in the third loop are all memory cell transistors MT of which the threshold voltages should eventually be at a level equal to or higher than the “B” state, and the memory cell transistors MT that failed in verification in the previous loops. In addition, the memory cell transistors MT to be verified for the “A” state in the third loop are memory cell transistor MT that failed in verification in the previous loops among the memory cell transistors MT of which the threshold voltages will eventually be at the “A” state. The memory cell transistors MT to be verified for the “B” state in the third loop are memory cell transistors MT of which the threshold voltages will eventually be at the “B” state.

In a fourth loop, after VPGM4 is applied to the selected word line WLsel, the same program and verification operations as in the third loop are performed. However, among the memory cell transistors MT of which the threshold voltages eventually be at the “A” state, those that passed verification at the “A” state in the third loop are excluded from targets for program and verification operations in the fourth loop. Similarly, the memory cell transistors MT that passed verification at the “B” state in the third loop are excluded from targets for program and verification operations in the fourth loop. In other words, in the fourth loop, memory cell transistors MT of which the threshold voltages eventually be at a level equal to or higher than the “C” state and memory cell transistors MT that failed in verification in the previous loops are targets for the program operation.

Similarly, in the subsequent loops, after a program operation, a verification operation is performed for each predetermined level as shown in FIG. 8. Memory cell transistors MT of which the threshold voltages reach a final target level are excluded from targets for program and verification operations in the next and subsequent loops.

As a loop is repeated, the number of memory cell transistors MT of which the threshold voltages reach the final target level increases, and thus the number of memory cell transistors MT that are excluded from targets for program and verification operations gradually increases. This is also shown in FIG. 10 where the number of levels marked as “1” increases and the number of levels marked as “0” decreases as a loop count increases.

It is noted that, in the example shown in FIG. 9, the verification operation for the “A” state is completed in a sixth loop. This is because, for example, from the characteristics of the memory cell array 21 obtained in advance, it is known that writing data to the “A” state is substantially completed after a total of six loops. Similarly, in the example shown in FIG. 9, the verification operation for the “B” state is completed in an eighth loop. This is because it is known that writing data to the “B” state is substantially completed after a total of six loops from the third loop to an eighth loop.

### 1.9 Configuration of Row Decoder

Next, a schematic configuration of the row decoder 27 will be described.

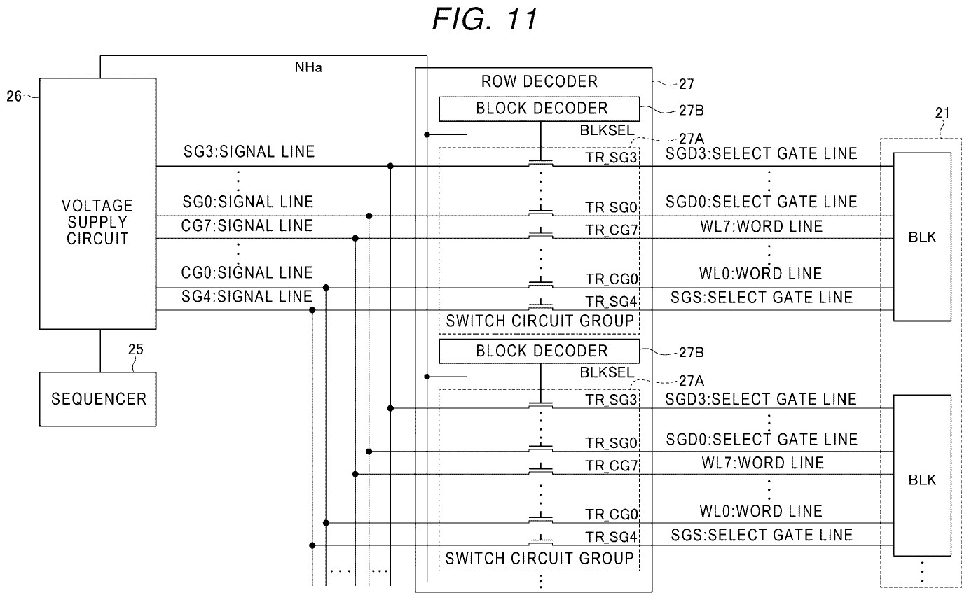

FIG. 11 is a block diagram showing an example of connection between the row decoder 27 and the memory cell array 21. The voltage supply circuit 26 generates various voltages including voltage required for program and read operations for the memory cell transistors MT. The voltage supply circuit 26 supplies voltages to signal lines SG0 to SG4 and CG0 to CG7. These signal lines SG0 to SG4 and CG0 to CG7 are branched by the row decoder 27 and connected to the wiring of each physical block BLK. In other words, the signal lines SG0 to SG3 function as global select gate lines, and are connected to the select gate lines SGD0 to SGD3 serving as local select gate lines in each physical block BLK via the row decoder 27. The signal lines CG0 to CG7 function as global word lines, and are connected to the word lines WL0 to WL7 serving as local word lines in each physical block BLK via the row decoder 27. The signal line SG4 functions as a global select gate line and is connected to the select gate line SGS serving as a local select gate line in each physical block BLK via the row decoder 27.

The row decoder 27 includes a plurality of switch circuit groups 27A corresponding to each block BLK, and a plurality of block decoders 27B provided respectively corresponding to the plurality of switch circuit groups 27A.

Each of the switch circuit groups 27A includes a plurality of transistors TR_SG0 to TR_SG4 provided between the signal lines SG0 to SG4 and the select gate lines SGD0 to SGD4. Each of the switch circuit groups 27A also includes a plurality of transistors TR_CG0 to TR_CG7 provided between the signal lines CG0 to CG7 and the word lines WL0 to WL7. Each of the transistors TR_SG0 to TR_SG4 and TR_CG0 to TR_CG7 is a high breakdown voltage transistor.

When each of the block decoders 27B is designated by a row address, it supplies a block selection signal BLKSEL at an “H” level to the switch circuit group 27A. The block selection signal BLKSEL is a signal in which the “H” level indicates a voltage VPGMH and the “L” level indicates a voltage Vss. The voltage VPGMH is a voltage higher than the program voltage VPGM. For example, when the program voltage VPGM is 20 V, the voltage VPGMH is set to 25 V. Below, the voltage VPGMH is also referred to as a “block selection voltage VPGMH”. When a block selection signal BLKSEL at an “H” level is supplied to a gate of each of the transistors TR_SG0 to TR_SG4 and TR_CG0 to TR_CG7 in the switch circuit group 27A, the transistors TR_SG0 to TR_SG4 and TR_CG0 to TR_CG7 are set to be in an on state and become conductive. For this reason, a voltage generated by the voltage supply circuit 26 is supplied to the select gate lines SGD0 to SGD3 and SGS and the word lines WL0 to WL7 in the block BLK to be operated via the signal lines SG0 to SG4 and CG0 to CG7.

Meanwhile, when each of the block decoders 27B is not designated by a row address, it supplies a block selection signal BLKSEL at an “L” level to the switch circuit group 27A. Thereby, the block selection signal BLKSEL at an “L” level is supplied to the gates of the transistors TR_SG0 to TR_SG4 and TR_CG0 to TR_CG7 in the switch circuit group 27A, and thus the transistors TR_SG0 to TR_SG4 and TR_CG0 to TR_CG7 are set to be in an off state and become non-conductive. For this reason, a voltage generated by the voltage supply circuit 26 is not supplied to the select gate lines SGD0 to SGD3 and SGS and the word lines WL0 to WL7 in the block BLK not to be operated.

### 1.10 Configuration of Voltage Generation Circuit

Next, a schematic configuration of the voltage supply circuit 26 will be described.

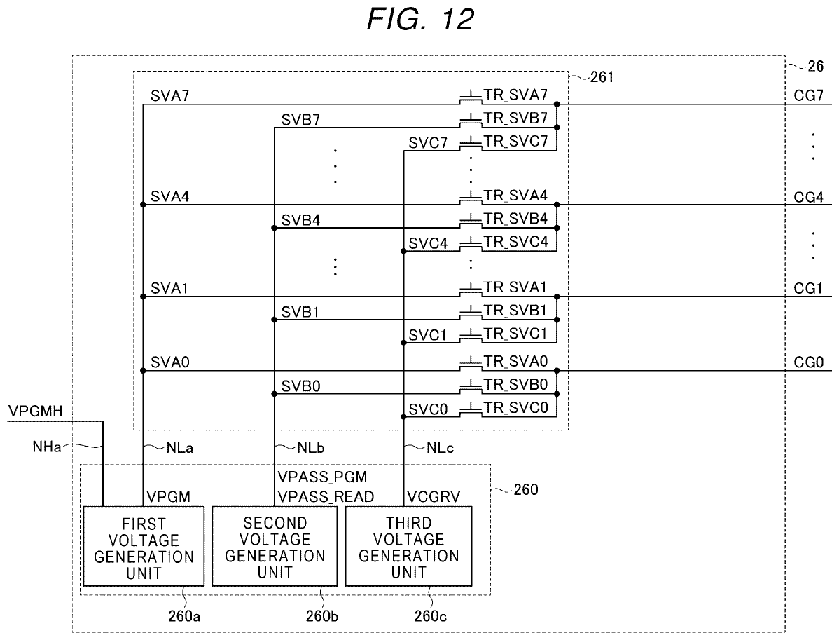

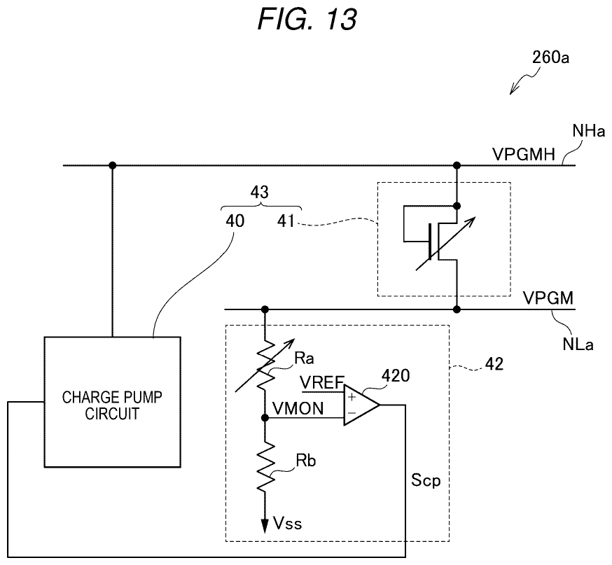

FIG. 12 is a block diagram showing the internal configuration of the voltage supply circuit 26. As shown in FIG. 12, the voltage supply circuit 26 includes a voltage generation circuit 260 and a multiplexer 261. It is noted that FIG. 12 shows only a configuration for applying a voltage to the signal lines CG0 to CG7 in the voltage supply circuit 26 and does not show a configuration for applying a voltage to the other signal lines SG0 to SG4.

The voltage generation circuit 260 includes a first voltage generation unit 260a, a second voltage generation unit 260b, and a third voltage generation unit 260c. The first voltage generation unit 260a generates a program voltage VPGM and a block selection voltage VPGMH that are applied to the selected word line WLsel during a write operation. An output node NLa that outputs the program voltage VPGM and an output node NHa that outputs the block selection voltage VPGMH are connected to the first voltage generation unit 260a. The second voltage generation unit 260b generates a program pass voltage VPASS_PGM that is applied to the non-selected word lines WLusel during a write operation, and a voltage VPASS_READ that is applied to the non-selected word lines WLusel during a read operation. The second voltage generation unit 260b is connected to an output node NLb that outputs the program pass voltage VPASS_PGM or the voltage VPASS_READ. The third voltage generation unit 260c generates a read voltage VCGRV that is applied to the selected word line WLsel during a read operation. The third voltage generation unit 260c is connected to an output node NLc that outputs the read voltage VCGRV.

In the multiplexer 261, the output node NLa of the first voltage generation unit 260a is connected to the signal lines CG0 to CG7 via a plurality of signal lines SVA0 to SVA7. Although not shown in the drawing, the output node NHa of the first voltage generation unit 260a is connected to each block decoder 27B of the row decoder 27. In addition, the output node NLb of the second voltage generation unit 260b is connected to the signal lines CG0 to CG7 via a plurality of signal lines SVB0 to SVB7. Further, the output node NLc of the third voltage generation unit 260c is connected to the signal lines CG0 to CG7 via a plurality of signal lines SVC0 to SVC7.

The multiplexer 261 includes transistors TR_SVA0 to TR_SVA7, TR_SVB0 to TR_SVB7, and TR_SVC0 to TR_SVC7. The transistors TR_SVA0 to TR_SVA7 are provided in the middle of the plurality of signal lines SVA0 to SVA7, respectively. The transistors TR_SVB0 to TR_SVB7 are provided in the middle of the plurality of signal lines SVB0 to SVB7, respectively. The transistors TR_SVC0 to TR_SVC7 are provided in the middle of the plurality of signal lines SVC0 to SVC7, respectively. The operation of each of the transistors TR_SVA0 to TR_SVA7, TR_SVB0 to TR_SVB7, and TR_SVC0 to TR_SVC7 is controlled by the sequencer 25.

The multiplexer 261 selectively applies voltages generated by the voltage generation units 260a, 260b, and 260c to the signal lines CG0 to CG7 by switching between turn-on and turn-off of each of the transistors TR_SVA0 to TR_SVA7, TR_SVB0 to TR_SVB7, and TR_SVC0 to TR_SVC7.

For example, when the word line WL7 is set as the selected word line WLsel during a write operation, in the multiplexer 261, first, the transistors TR_SVB0 to TR_SVB7 are turned on, and the other transistors TR_SVA0 to TR_SVA7 and TR_SVC0 to TR_SVC7 are turned off, thereby supplying the program pass voltage VPASS_PGM to each of the word lines WL0 to WL7 from the second voltage generation unit 260b via the signal lines CG0 to CG7. Thereafter, when the time arrives to boost the program pass voltage VPASS_PGM to the program voltage VPGM, the transistor TR_SVB7 corresponding to the word line WL7, which is the selected word line WLsel, is turned off, and the transistor TR_SVA7 is turned on, thereby boosting the voltage of the word line WL7 from the program pass voltage VPASS_PGM to the program voltage VPGM.

Meanwhile, the first voltage generation unit 260a according to this embodiment generates a preparation voltage VPGM_prep higher than the program pass voltage VPASS_PGM before the transistor TR_SVA7 is turned on. When the transistor TR_SVA7 is turned on, the first voltage generation unit 260a outputs the preparation voltage VPGM_prep as indicated by an alternating dotted-dashed line in FIG. 6, and then outputs the program voltage VPGM. Thereby, it is possible to smoothly boost the voltage of the word line WL7, which is the selected word line WLsel, from the program pass voltage VPASS_PGM to the program voltage VPGM.

In addition, when the word line WL7 is set as the selected word line WLsel during a read operation, the multiplexer 261 applies the read voltage VCGRV to the signal line CG7 connected to the selected word line WL7 by turning on the transistor TR_SVC7 and turning off the transistors TR_SVA7 and TR_SVB7. In addition, the multiplexer 261 applies the read pass voltage VPASS_READ to the other signal lines CG0 to CG6 connected to the non-selected word lines WL0 to WL6 by turning on the transistors TR_SVB0 to TR_SVB6 and turning off the transistors TR_SVA0 to TR_SVA6 and TR_SVC0 to TR_SVC6.

### 1.11 Configuration of Voltage Generation Unit

Next, a schematic configuration of the first voltage generation unit 260a will be described.

FIG. 13 is a circuit diagram showing a schematic circuit configuration of the first voltage generation unit 260a. As shown in FIG. 13, the first voltage generation unit 260a includes a charge pump circuit 40, a voltage difference generation circuit 41, and a detection circuit 42.

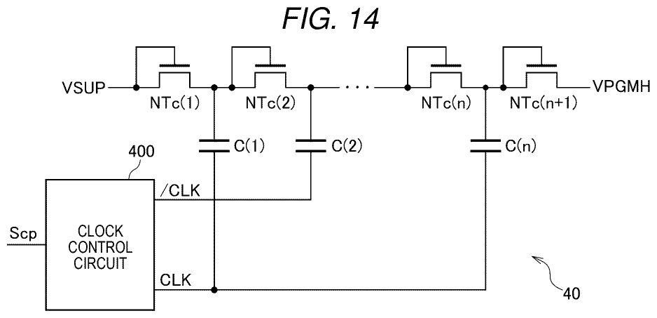

FIG. 14 is a circuit diagram showing an example of a circuit configuration of the charge pump circuit 40. As shown in FIG. 14, the charge pump circuit 40 includes a clock control circuit 400, NMOS transistors NTc(1) to NTc(n+1), and capacitors C(1) to C(n). It is noted that n is any integer.

The clock control circuit 400 generates clock signals CLK and /LK. The clock signal /LK is an inverted signal of the clock signal CLK. The clock control circuit 400 supplies the complementary clock signals CLK and /LK to the charge pump circuit 40. The charge pump circuit 40 generates a block selection voltage VPGMH by using the clock signals CLK and /LK supplied from the clock control circuit 400.

The NMOS transistors NTc(1) to NTc(n+1) each function as a diode by being diode-connected, that is, by electrically connecting the drain and the gate. The NMOS transistors NTc(1) to NTc(n+1) are connected in series with their current paths in a forward direction.

One end of each of the capacitors C(1) to C(n) is electrically connected to one end on the output side of the current path of each of the NMOS transistors NTc(1) to NTc(n). The clock signal CLK is supplied to the other end of each of the capacitors C1, C3, C5, . . . , and the clock signal /LK is supplied to the other end of each of the capacitors C2, C4, C6, . . . .

A voltage VSUP (for example, a power supply voltage Vdd) is supplied to one end on the input side of the current path of the NMOS transistor NTc(1). Then, the capacitors C(1) to C(n) are repeatedly charged and discharged by the clock signals CLK and /LK, which have an amplitude of the power supply voltage Vdd, for example, and the input voltage VSUP is boosted and sequentially transferred to the subsequent stages. As a result, a block selection voltage VPGMH that is higher than the voltage VSUP is generated on the output side of the current path of the NMOS transistor NTc(n+1).

As shown in FIG. 13, the charge pump circuit 40 outputs the generated block selection voltage VPGMH to the output node NHa.

The voltage difference generation circuit 41 is provided between the output nodes NHa and NLa. The voltage difference generation circuit 41 generates a voltage difference ΔV between the output nodes NHa and NLa. The voltage difference ΔV is a voltage difference to be generated between the program voltage VPGM and the block selection voltage VPGMH, and is, for example, 5 V. The voltage difference generation circuit 41 can be, for example, a single diode-connected NMOS transistor as shown in FIG. 13, or a plurality of diode-connected NMOS transistors electrically connected in series. In this embodiment, the output nodes NHa and NLa are examples of voltage output lines.

The detection circuit 42 includes a variable resistor Ra, a reference resistor Rb, and a comparison circuit 420.

The variable resistor Ra and the reference resistor Rb are electrically connected in series between the output node NLa and the ground voltage Vss. A connection point Pcr between the variable resistor Ra and the reference resistor Rb is connected to one input terminal of the comparison circuit 420. Thus, a voltage VMON generated by dividing the voltage of the output node NLa by the variable resistor Ra and the reference resistor Rb is applied to one input terminal of the comparison circuit 420. In the following, this voltage VMON will also be referred to as a “monitor voltage VMON.”

A reference voltage VREF is applied to the other input terminal of the comparison circuit 420. The reference voltage VREF is set to a voltage that should appear at the connection point Pcr when the voltage output to the output node NLa becomes the specified program voltage VPGM. When the monitor voltage VMON is higher than the reference voltage VREF, the comparison circuit 420 outputs a stop signal Scp to the clock control circuit 400 of the charge pump circuit 40. The clock control circuit 400 stops generating the clock signals CLK and /LK during a period when the stop signal Scp is being output from the comparison circuit 420. Thereby, the charge pump circuit 40 is stopped. In this embodiment, the comparison circuit 420 is an example of a detection unit.

Next, an example of the operation of the first voltage generation unit 260a will be described.

For example, when the voltage appearing at the output node NLa exceeds the specified program voltage VPGM, the monitor voltage VMON becomes higher than the reference voltage VREF, and the comparison circuit 420 generates a stop signal Scp. The clock control circuit 400 stops generating the clock signals CLK and /LK by the stop signal Scp. As a result, the output voltage of the charge pump circuit 40 drops to curb a voltage rise at the output node NLa, and the voltage of the output node NLa is maintained at the specified program voltage VPGM. In addition, when the voltage appearing at the output node NLa is lower than the specified program voltage VPGM, the comparison circuit 420 does not generate the stop signal Scp, and thus the charge pump circuit 40 continues to operate. As a result, the voltage of the output node NLa rises, and the voltage of the output node NLa is maintained at the specified program voltage VPGM.

In the first voltage generation unit 260a, a feedback loop is configured with the charge pump circuit 40, the voltage difference generation circuit 41, the resistors Ra and Rb, the comparison circuit 420, and the clock control circuit 400, and the program voltage VPGM is determined by controlling the resistance voltage division of the resistors Ra and Rb. The output voltage of the charge pump circuit 40 changes to obtain the program voltage VPGM, and a block selection voltage VPGMH that is higher than the program voltage VPGM by ΔV is obtained.

In this manner, in the first voltage generation unit 260a, the charge pump circuit 40 and the voltage difference generation circuit 41 make up a voltage adjustment unit 43 that adjusts the voltage VPGM applied to the output node NLa based on the voltage VMON detected by the comparison circuit 420.

### 1.12 Configuration of Detection Circuit

Next, a specific configuration of the detection circuit will be described.

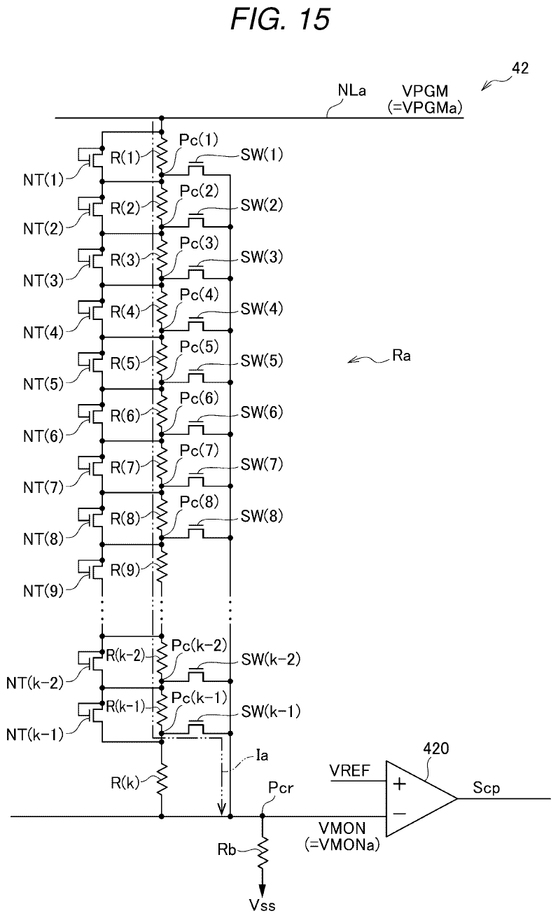

FIG. 15 is a circuit diagram showing a schematic configuration of the detection circuit 42. As shown in FIG. 15, the variable resistor Ra includes a plurality of resistance elements R(1) to R(k), a plurality of switching elements SW(1) to SW(k−1), and NMOS transistors NT(1) to NT(k−1). It is noted that k is an integer of 2 or more.

The plurality of resistance elements R(1) to R(k) are electrically connected in series in this order. An upper end of the resistance element R(1) disposed on the highest voltage side is connected to the output node NLa. A lower end of the resistance element R(k) disposed on the lowest voltage side is connected to the connection point Pcr. In FIG. 15, connection points of the resistance elements R(1) to R(k) are indicated as Pc(1), Pc(2), . . . , Pc(k−1).

The switching element SW(1) is provided between the connection point Pc(1) between the resistance element R(1) and the resistance element R(2), which are connected in series, and the connection point Pcr. Similarly, the other switching elements SW(2) to SW(k−1) are provided between the connection points Pc(2) to Pc(k−1) of the resistance elements R(2) to R(k) and the connection point Pcr, respectively. Each of the switching elements SW(1) to SW(k−1) is configured with, for example, an NMOS transistor. Switching between turn-on and turn-off of each of the switching elements SW(1) to SW(k−1) is controlled by the sequencer 25 shown in FIG. 2.

The NMOS transistors NT(1) to NT(k−1) are electrically connected in parallel to the plurality of resistance elements R(1) to R(k−1). Each of the NMOS transistors NT(1) to NT(k−1) functions as a diode by being diode-connected. The NMOS transistors NT(1) to NT(k−1) are disposed such that their current paths are in a forward direction. For example, the drain of the NMOS transistor NT(1) is connected to a high-potential-side portion of the resistance element R(1), and the source of the NMOS transistor NT(1) is connected to a low-potential-side portion of the resistance element R(1).

Next, an example of the operation of the detection circuit 42 will be described.

Based on the magnitude of the program voltage VPGM to be generated, the sequencer 25 turns on one of the plurality of switching elements SW(1) to SW(k−1) and turns off all of the other switching elements.

For example, the sequencer 25 turns on the switching element SW(k−1) and turns off the other switching elements SW(1) to SW(k−2). Thereby, a low-potential-side portion of the switching element SW(k−1) is connected to the connection point Pcr, and a current path is generated between the output node NLa and the connection point Pcr as indicated by an arrow of an alternating two dots-dashed line Ia in FIG. 15. In other words, a circuit is formed between the output node NLa and the connection point Pcr such that the resistance elements R(1) to R(k−1) are electrically connected in series. Thus, the resistance value of the variable resistor Ra is the sum of the resistance values of the resistance elements R(1) to R(k−1). Thus, the monitor voltage VMON is set to a voltage VMONa that is obtained by dividing the voltage of the output node NLa by the sum of the resistance values of the resistance elements R(1) to R(k−1) and the reference resistor Rb. As a result, a program voltage VPGMa having a magnitude corresponding to the voltage VMONa is generated at the output node NLa. The program voltage VPGMa is, for example, one of the program voltages VPGM1 to VPGM19 and the preparation voltage VPGM_prep.

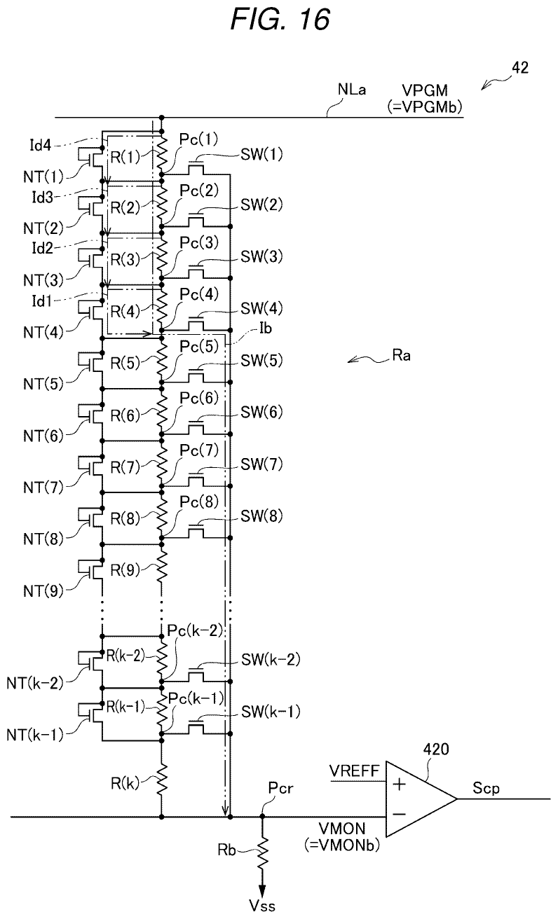

Meanwhile, when the program voltage is changed from VPGMa to VPGMb, the sequencer 25 switches, for example, the switching element SW(4) from a turn-off state to a turn-on state and switches the switching element SW(k−1) from a turn-on state to a turn-off state. Thereby, a low-potential-side portion of the switching element SW(4) is connected to the connection point Pcr, and a current path is generated between the output node NLa and connection point Pcr as indicated by an arrow of an alternating two dots-dashed line Ib in FIG. 16. In other words, a circuit is configured between the output node NLa and connection point Pcr such that the resistance elements R(1) to R(4) are electrically connected in series. Accordingly, the resistance value of the variable resistor Ra is the sum of the resistance values of the resistance elements R(1) to R(4). Thus, the monitor voltage VMON is changed to a voltage VMONb obtained by dividing the voltage of the output node NLa by the sum of the resistance values of the resistance elements R(1) to R(4) and the reference resistor Rb. As a result, a program voltage VPGMb having a magnitude corresponding to the voltage VMONb is generated at the output node NLa. The program voltage VPGMb is, for example, one of the program voltages VPGM1 to VPGM19 or the preparation voltage VPGM_prep.

In this manner, the detection circuit 42 can generate various program voltages VPGM1 to VPGM19 and the preparation voltage VPGM_prep by selectively turning on one of the switching elements SW(1) to SW(k−1) and turning off the other switching elements.

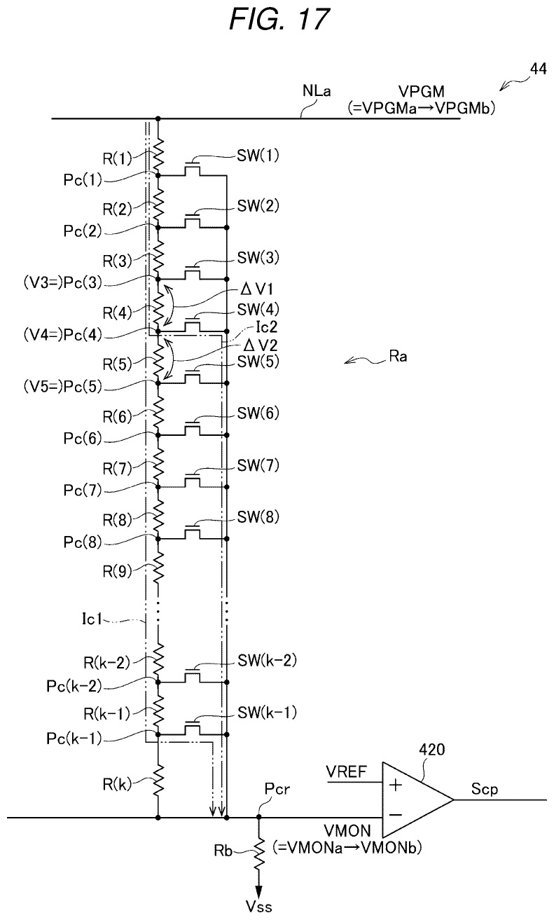

Next, the operations and effects of the detection circuit 42 according to this embodiment shown in FIGS. 15 and 16 will be described while describing a detection circuit 44 according to a reference example shown in FIG. 17.

The detection circuit 44 according to the reference example shown in FIG. 17 has the same structure as the detection circuit 42 according to this embodiment shown in FIGS. 15 and 16, except that it does not include NMOS transistors NT(1) to NT(k−1). In the detection circuit 44 according to the reference example shown in FIG. 17, when the switching element SW(k−1) is turned on and the other switching elements SW(1) to SW(k−2) are turned off, a current path is formed as indicated by an alternating two dots-dashed line Ic1 in the drawing, similarly to the detection circuit 42 according to this embodiment shown in FIG. 15, and thus the monitor voltage VMON is set to the voltage VMONa. Thereby, the program voltage VPGMa is output to the output node NLa. At this time, when a voltage at a connection point Pc(3) between a resistance element R(3) and a resistance element R(4) is defined as V3, a voltage at a connection point Pc(4) between the resistance element R(4) and a resistance element R(5) is defined as V4, and the voltage at a connection point Pc(5) between the resistance element R(5) and a resistance element R(6) is defined as V5, a relationship of “VMONa<<V5<V4<V3” is established between these voltages Va, Vb, Vc, and VMONa.

In the detection circuit 44 according to the reference example, when the program voltage to be output to the output node NLa is changed from VPGMa to VPGMb, the switching element SW(4) is switched from a turn-off state to a turn-on state, and the switching element SW(k−1) is switched from a turn-on state to a turn-off state, in the same manner as the detection circuit 42 according to this embodiment shown in FIG. 16. Thereby, a new current path is formed as indicated by an alternating two dots-dashed line Ic2 in the drawing, and thus the voltage at the connection point Pc(4) between the resistance elements R(4) and R(5) drops sharply from the voltage V4 toward the voltage VMONa. For this reason, there is a possibility that a large difference ΔV1 may occur between the voltage at the connection point Pc(4) between the resistance elements R(4) and R(5) and the voltage at the connection point Pc(3) between the resistance elements R(3) and R(4). As a result, a voltage difference close to or exceeding a breakdown voltage violation may occur at both ends of the resistance element R(4). Similarly, there is a possibility that a large difference ΔV2 may occur between the voltage at the connection point Pc(4) between the resistance element R(4) and the resistance element R(5) and the voltage at the connection point Pc(5) between the resistance element R(5) and the resistance element R(6). As a result, there is a possibility that a voltage difference close to or exceeding a breakdown voltage violation may occur at both ends of the resistance element R(5).

Such a breakdown voltage violation in the resistance elements R(1) to R(k) is highly likely to become evident when the voltage output from the first voltage generation unit 260a to the output node NLa needs to be switched from the preparation voltage VPGM_prep to the program voltage VPGM in a short period of time, for example, as indicated by an alternating dotted-dashed line in FIG. 6, that is, when switching between turn-on and turn-off of each of the switching elements SW(1) to SW(k−1) is performed in a short period of time.

In this respect, the detection circuit 42 according to this embodiment shown in FIG. 16 differs from the detection circuit 44 according to the reference example in that the NMOS transistors NT(1) to NT(k−1) are electrically connected in parallel to the resistance elements R(1) to R(k−1), respectively. According to the configuration of the detection circuit 42 in this embodiment, when the voltage at the connection point Pc(4) between the resistance elements R(4) and R(5) drops as a result of the switching element SW(4) being turned on, a current path as indicated by an alternating two dots-dashed line Id1 in FIG. 16 is generated. That is, when the voltage at the connection point Pc(4) drops, and a voltage difference greater than the threshold voltage of the NMOS transistor NT(4) occurs between the connection point Pc(4) and the connection point Pc(3) between the resistance elements R(3) and R(4), the NMOS transistor NT(4) is set to be in an on state. Thereby, a current path that flows from connection point Pc(3) to the connection point Pc(4) via the NMOS transistor NT(4) is formed as indicated by the alternating two dots-dashed line Id1 in the drawing, making it difficult for the voltage at the connection point Pc(4) to drop. As a result, a voltage difference between the connection points Pc(3) and Pc(4) becomes less likely to become large, and a voltage difference between the connection points Pc(4) and Pc(5) also becomes less likely to become large, making it difficult to cause a breakdown voltage violation in the resistance elements R(4) and R(5).

Furthermore, when the voltage at the connection point Pc(3) between the resistance elements R(3) and R(4) drops due to the formation of the current path as indicated by the alternating two dots-dashed line Id1 in the drawing, there is a possibility that a large voltage difference may occur in the connection point Pc(2) between the resistance elements R(2) and R(3) and the connection point Pc(3) between the resistance elements R(3) and R(4). In this case, there is a possibility that a current path may be further formed as indicated by an alternating two dots-dashed line Id2 in the drawing. That is, when a voltage difference greater than the threshold voltage of the NMOS transistor NT(3) occurs between the connection point Pc(3) and the connection point Pc(2) due to a drop in the voltage at the connection point Pc(3), the NMOS transistor NT(3) is set to be in an on state. Thereby, the current path flowing from the connection point Pc(2) to the connection point Pc(4) via the NMOS transistors NT(3) and NT(4) is further generated as indicated by the alternating two dots-dashed line Id2 in the drawing, making it more difficult for the voltage at the connection point Pc(4) to drop. As a result, the voltage difference between the connection points Pc(3) and Pc(4) becomes less likely to become large, and the voltage difference between the connection points Pc(4) and Pc(5) also becomes less likely to become large, making it difficult to cause a breakdown voltage violation in the resistance elements R(4) and R(5).

Similarly, there is a possibility that a current path will be further formed as indicated by alternating two dots-dashed lines Id3 and Id4 in the drawing. Thereby, since the voltage at the connection point Pc(4) is less likely to drop further, the voltage difference between the connection points Pc(3) and Pc(4) is less likely to increase, and the voltage difference between the connection points Pc(4) and Pc(5) is also less likely to increase. Thus, a breakdown voltage violation is less likely to occur in the resistance elements R(4) and R(5).

### 1.13 Operations and Effects of Voltage Generation Circuit of First Embodiment

As described above, the voltage generation circuit 260 according to this embodiment includes the variable resistor Ra, the reference resistor Rb, the comparison circuit 420, and the voltage adjustment unit 43. The variable resistor Ra is connected to the output node NLa. The reference resistor Rb is connected in series to the low-voltage side of the variable resistor Ra. The comparison circuit 420 detects the monitor voltage VMON at the connection point Pcr between the variable resistor Ra and the reference resistor Rb. The voltage adjustment unit 43 adjusts the program voltage VPGM applied to the output node NLa based on the monitor voltage VMON detected by the comparison circuit 420. The variable resistor Ra includes the plurality of resistance elements R(1) to R(k), the plurality of switching elements SW(1) to SW(k−1), and the plurality of NMOS transistors NT(1) to NT(k−1). The plurality of resistance elements R(1) to R(k) are connected in series. The plurality of switching elements SW(1) to SW(k−1) are provided between the connection points Pc(1), Pc(2), . . . , Pc(k−1) of the plurality of resistance elements R(1) to R(k) and the connection point Pcr. The plurality of NMOS transistors NT(1) to NT(k−1) function as diodes and are connected in parallel to the plurality of resistance elements R(1) to R(k−1), respectively.

According to this configuration, when one of the switching elements SW(1) to SW(k−1) is assumed to be SW(i), it is possible to prevent the voltage at the connection point Pc(i) between the resistance elements R(i) and R(i+1) from suddenly dropping when the switching element SW(i) is switched from a turn-off state to a turn-on state. It is noted that i=1, 2, . . . , k−1. Thereby, it is possible to prevent a large voltage difference from occurring at both ends of each of the resistance elements R(i) and R(i+1), making it possible to improve the breakdown voltage performance of the voltage generation circuit 260.

The NMOS transistors NT(1) to NT(k−1) are disposed in a forward direction with respect to the current paths of the resistance elements R(1) to R(k).

According to this configuration, when one switching element SW(i) of the switching elements SW(1) to SW(k−1) is switched from a turn-off state to a turn-on state, a current path flowing from the connection points Pc(1) to Pc(i−1) to the connection points Pc(i) via the NMOS transistors NT(1) to NT(i) is formed, and thus it is possible to prevent the voltage at the connection points Pc(i) from dropping.

The same number of NMOS transistors NT(1) to NT(k−1) as the number of switching elements SW(1) to SW(k−1) are provided.

According to this configuration, since the NMOS transistors NT(1) to NT(k−1) can be respectively disposed for the plurality of switching elements SW(1) to SW(k−1), it is possible to more reliably prevent a breakdown voltage violation from occurring in the resistance elements R(1) to R(k).

### 1.14 First Modification Example

Next, a first modification example of the voltage generation circuit 260 according to the first embodiment will be described.

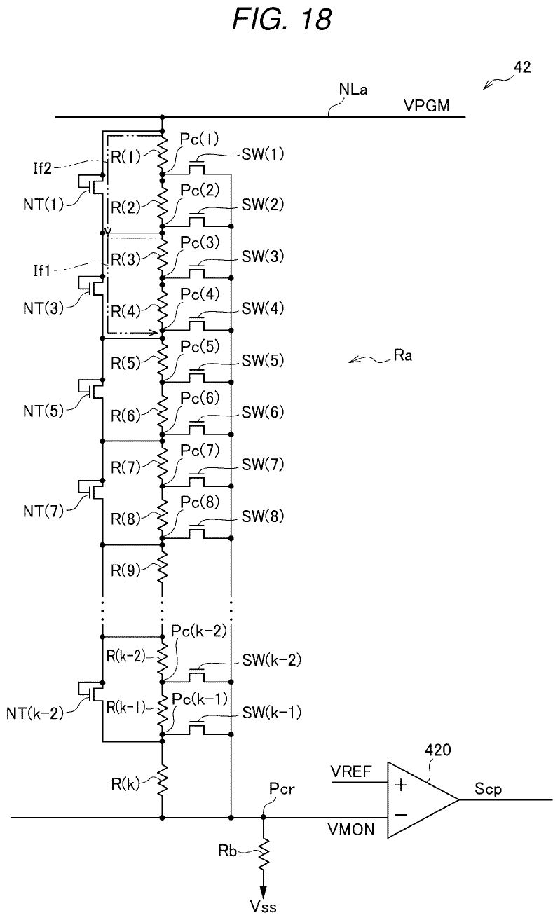

As shown in FIG. 18, in the detection circuit 42 according to this modification example, when j=1, 3, 5, . . . , k−1, one NMOS transistor NT(j) is connected in parallel to two resistance elements R(j) and R(j+1).

Even with such a configuration, for example, when the voltage at the connection point Pc(4) between the resistance element R(4) and the resistance element R(5) drops, the NMOS transistor NT(3) is set to be in an on state, and a current path flowing from the connection point Pc(2) to the connection point Pc(4) via the NMOS transistor NT(3) is formed as indicated by an alternating two dots-dashed line If1 in the drawing. For this reason, the voltage at the connection point Pc(4) is less likely to drop. In addition, a current path is further formed as indicated by an alternating two dots-dashed line If2 in the drawing, and thus there is also a possibility that the voltage at the connection point Pc(4) will be less likely to drop. As a result, the voltage difference between the connection points Pc(3) and Pc(4) becomes less likely to become large, and the voltage difference between the connection points Pc(4) and Pc(5) also becomes less likely to become large, making it difficult to cause a breakdown voltage violation in the resistance elements R(4) and R(5).

### 1.15 Second Modification Example

Next, a second modification example of the voltage generation circuit 260 according to the first embodiment will be described.

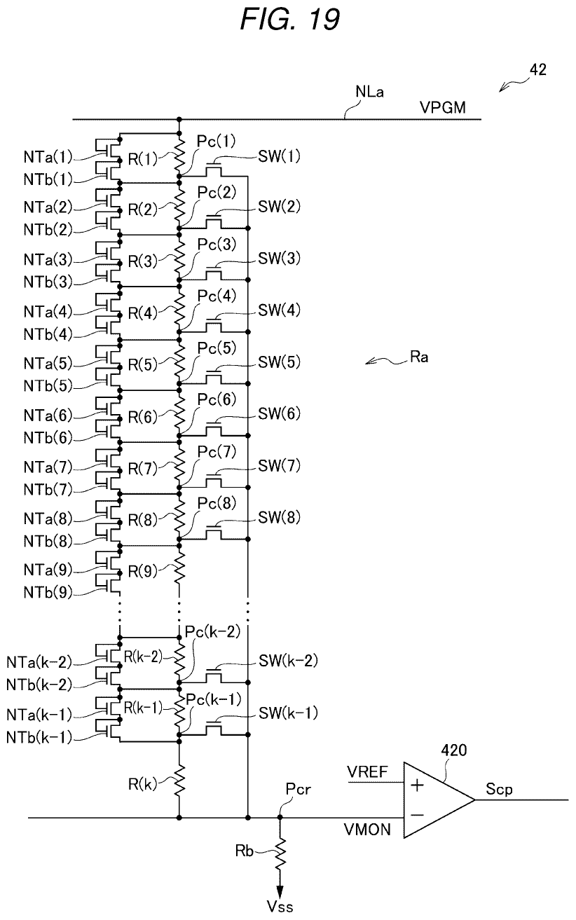

As shown in FIG. 19, in the detection circuit 42 according to this modification example, when i=1, 2, . . . , k−1, two NMOS transistors NTa(i) and NTb(i) connected in series are provided with respect to one resistance element R(i). Even with such a configuration, it is possible to obtain the same or similar operations and effects as those of the voltage generation circuit 260 according to the above-described embodiment.

### 1.16 Third Modification Example

Next, a third modification example of the voltage generation circuit 260 according to the first embodiment will be described.

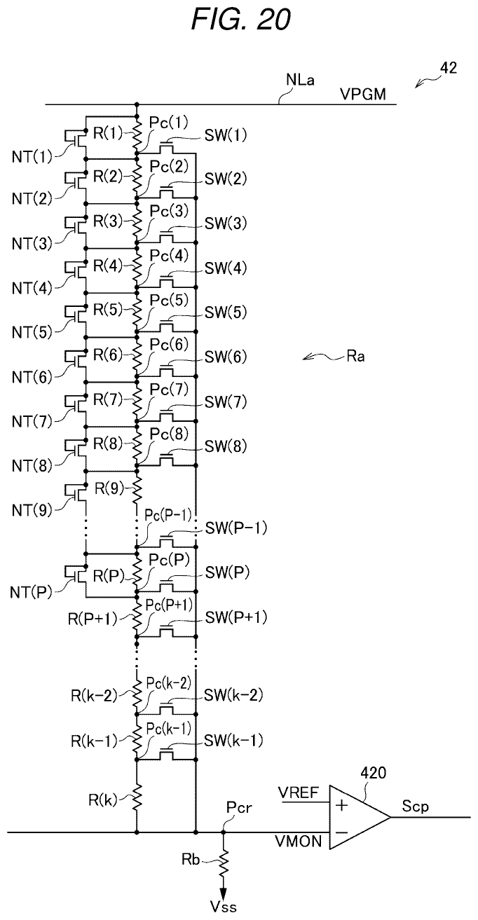

As shown in FIG. 20, in the detection circuit 42 according to this modification example, a plurality of resistance elements R(1) to R(k) include resistance elements R(1) to R(p) to which NMOS transistors NT(1) to NT(p) are connected in parallel, and resistance elements R(p+1) to R(k) to which NMOS transistors are not connected in parallel. It is noted that p is an integer that satisfies “2≤p≤k−2”. The resistance elements R(1) to R(p) are disposed on the higher voltage side than the resistance elements R(p+1) to R(k). In this modification example, the resistance elements R(1) to R(p) are examples of first resistance elements, and the resistance elements R(p+1) to R(k) are examples of second resistance elements.

In the detection circuit 42, a voltage drop at the connection point between the two resistance elements is greater when high-voltage-side switching elements SW(1) to SW(p) are switched from a turn-off state to a turn-on state than when low-voltage-side switching elements SW(p+1) to SW(k−1) are switched from a turn-off state to a turn-on state, and thus a breakdown voltage violation is more likely to occur in the first resistance elements. For this reason, as shown in FIG. 20, when NMOS transistors NT(1) to NT(p) are disposed only in the high-voltage-side resistance elements R(1) to R(p), it is possible to reduce the size of the detection circuit 42 by eliminating the need for NMOS transistors NT(p+1) to NT(k−1) while curbing the occurrence of a breakdown voltage violation in the resistance elements R(1) to R(k).

### 2 Second Embodiment

Next, a semiconductor memory device 2 according to a second embodiment will be described. The following will focus on differences from the semiconductor memory device 2 according to the first embodiment.

In the detection circuit 42 according to the first embodiment shown in FIG. 16, it is necessary to prevent a current from flowing through the NMOS transistors NT(1) to NT(k−1) during a normal operation. For this reason, when i=1, 2, . . . , k−1, it is necessary to make a threshold voltage of an NMOS transistor NT(i) higher than a voltage difference generated at both ends of the resistance element R(i) during a normal operation. However, there is a possibility that the voltage difference generated at both ends of the resistance element R(i) during a normal operation will become higher than the threshold voltage of the NMOS transistor NT(i) for some reason. In such a situation, when an unintended current path flowing through the NMOS transistor NT(i) is generated, there is a possibility that the detection circuit 42 will operate erroneously.

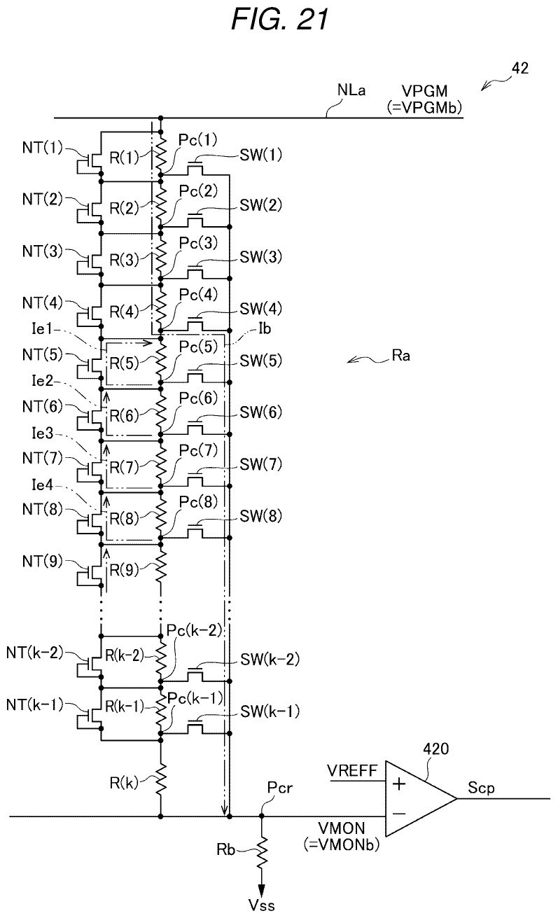

Consequently, in the detection circuit 42 according to this embodiment, as shown in FIG. 21, the NMOS transistors NT(1) to NT(k−1) that function as diodes are disposed in the opposite direction to the current paths of the resistance elements R(1) to R(k−1).

Next, the operations and effects of the detection circuit 42 according to this embodiment will be described.

In the detection circuit 42 according to this modification example, when the switching element SW(4) is turned on, a current path is generated as indicated by an arrow of an alternating two dots-dashed line Ib in FIG. 16, and the voltage at the connection point Pc(4) between the resistance element R(4) and the resistance element R(5) drops, a current path is generated as indicated by an alternating two dots-dashed line Ie1 in the drawing. That is, when a voltage difference greater than the threshold voltage of the NMOS transistor NT(5) occurs between the connection point Pc(4) and the connection point Pc(5) between the resistance elements R(5) and R(6) due to a voltage drop at the connection point Pc(4), the NMOS transistor NT(5) is set to be in an on state. Thereby, the current path flowing from the connection point Pc(5) to the connection point Pc(4) via the NMOS transistor NT(5) is generated as indicated by the alternating two dots-dashed line Ie1 in the drawing, and thus the voltage at the connection point Pc(4) is less likely to drop. As a result, the voltage difference between the connection points Pc(3) and Pc(4) becomes less likely to become large, and the voltage difference between the connection points Pc(4) and Pc(5) also becomes less likely to become large, making it difficult to cause a breakdown voltage violation in the resistance elements R(4) and R(5).

In addition, when a current path is formed as indicated by the alternating two dots-dashed line Ie1 in the drawing, and thus the voltage at the connection point Pc(5) between the resistance element R(5) and the resistance element R(6) drops, there is a possibility that a large voltage difference will occur between the connection point Pc(5) between the resistance elements R(5) and R(6) and the connection point Pc(6) between the resistance elements R(6) and R(7). In this case, there is a possibility that a current path will be further formed as indicated by an alternating two dots-dashed line Ie2 in the drawing. That is, when a voltage difference greater than the threshold voltage of the NMOS transistor NT(6) occurs between the connection point Pc(5) and the connection point Pc(6) due to a voltage drop at the connection point Pc(5), the NMOS transistor NT(6) is set to be in an on state. Thereby, a current path flowing from the connection point Pc(6) to the connection point Pc(4) via the NMOS transistors NT(6) and NT(5) is further generated as indicated by the alternating two dots-dashed line Ie2 in the drawing, and thus the voltage at the connection point Pc(4) is less likely to drop. As a result, the voltage difference between the connection points Pc(3) and Pc(4) becomes less likely to become large, and the voltage difference between the connection points Pc(4) and Pc(5) also becomes less likely to become large, making it difficult to cause a breakdown voltage violation in the resistance elements R(4) and R(5).

Similarly, there is a possibility that current paths will be further formed as indicated by alternating two dots-dashed lines Ie3, Ie4, and the like in the drawing. Thereby, since the voltage at the connection point Pc(4) is less likely to drop further, the voltage difference between the connection points Pc(3) and Pc(4) is less likely to increase, and the voltage difference between the connection points Pc(4) and Pc(5) is also less likely to increase. Thus, a breakdown voltage violation is less likely to occur in the resistance elements R(4) and R(5).

Furthermore, the NMOS transistors NT(1) to NT(k−1) that function as diodes are disposed in the opposite direction to the current paths of the resistance elements R(1) to R(k−1), and thus it is possible to prevent the formation of an unintended current path flowing through the NMOS transistors NT(1) to NT(k−1) during a normal operation, making it possible to curb an erroneous operation of the detection circuit 42.

### 3 Other Embodiments

The present disclosure is not limited to the above-described specific examples.

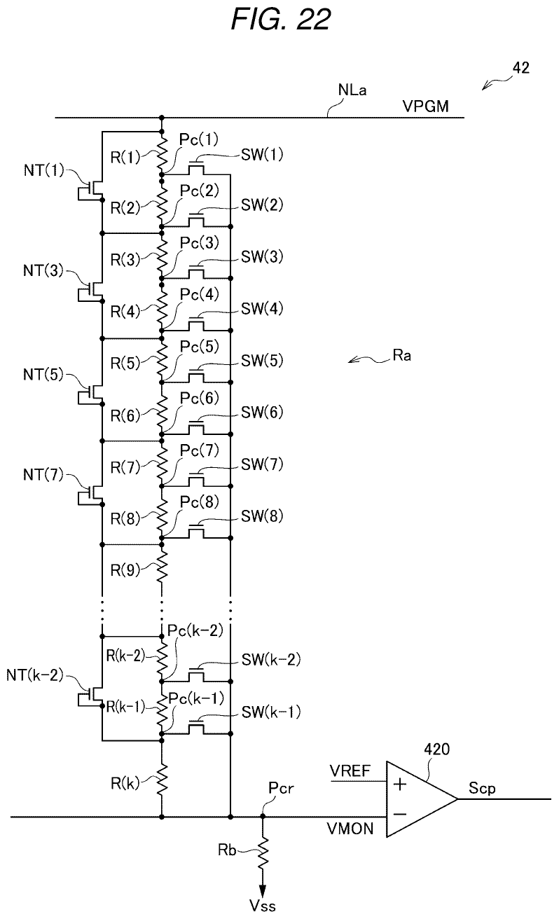

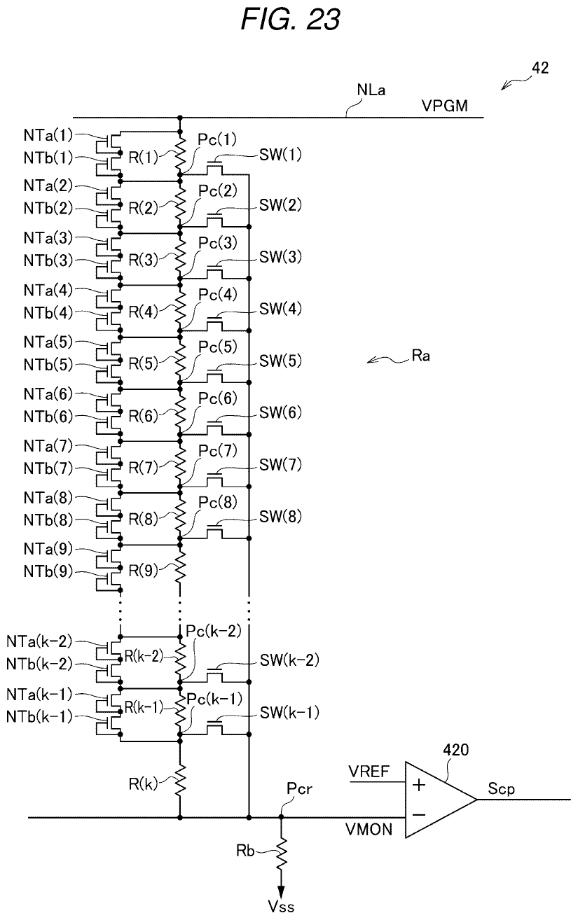

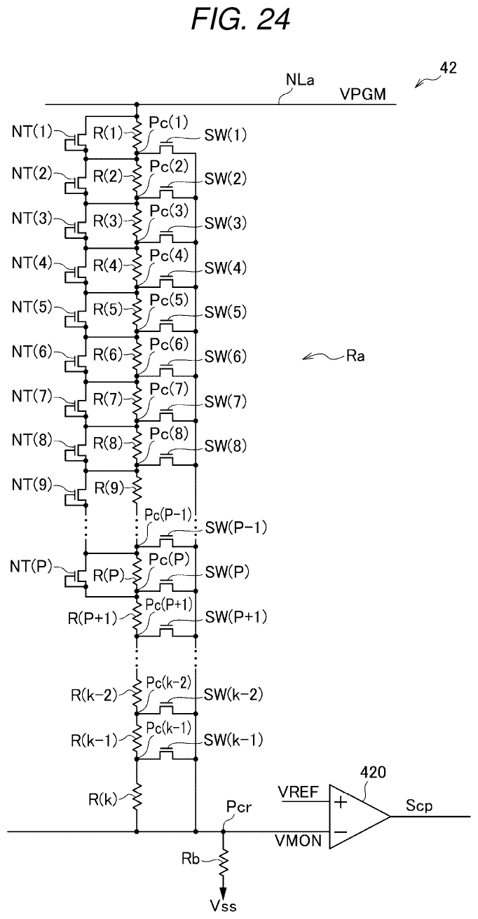

For example, the detection circuit 42 according to the second embodiment can adopt the configurations of the first to third modification examples of the first embodiment. That is, the detection circuit 42 according to the second embodiment can adopt the configurations shown in FIGS. 22 to 24.

In the detection circuit 42, it is sufficient that an NMOS transistor functioning as a diode is connected in parallel to at least one of the plurality of resistance elements R(1) to R(k).

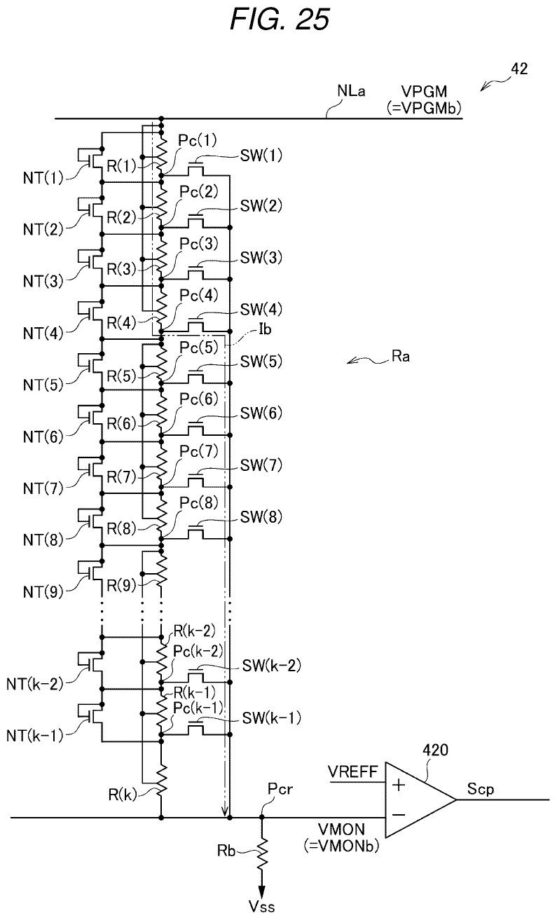

The resistance elements R(1) to R(k) may be, for example, three-terminal resistance elements as shown in FIG. 25. For example, a P-type diffused resistance element can be used as the three-terminal resistance element.

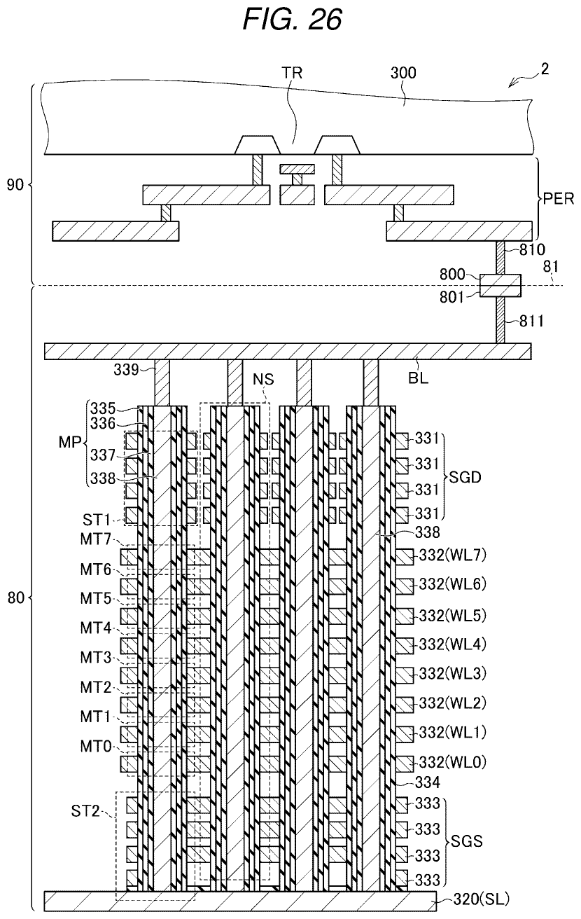

The structure of the semiconductor memory device 2 is not limited to the structure shown in FIG. 4 and can be appropriately modified. For example, the semiconductor memory device 2 may have a CMOS bonding array (CBA) structure as shown in FIG. 26. In the semiconductor memory device 2 shown in FIG. 26, a memory unit 80 provided with the memory cell array 21 and a control circuit unit 90 provided with the peripheral circuit PER are manufactured separately. The semiconductor memory device 2 is configured by bonding and joining the memory unit 80 and the control circuit unit 90, which are manufactured separately, at a bonding surface B1. The memory cell array 21 and the peripheral circuit PER are electrically connected to each other via wiring layers 800 and 801 and vias 810 and 811 provided on the bonding surface 81.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A voltage generation circuit comprising:
a variable resistor that is connected to a voltage output line;
a reference resistor that is connected in series to a low-voltage side of the variable resistor;
a detection circuit configured to detect a voltage at a first connection point between the variable resistor and the reference resistor; and
a voltage adjustment circuit configured to adjust a voltage at the voltage output line, based on the voltage detected by the detection circuit,
wherein the variable resistor includes
a plurality of resistance elements that are connected in series between the voltage output line and the first connection point,
a plurality of switching elements that are respectively provided between second connection points, each of which is located between a different adjacent pair of the resistance elements, and the first connection point, and
a diode that is connected in parallel to at least one of the plurality of resistance elements.

2. The voltage generation circuit according to claim 1, wherein the diode is disposed in a forward direction with respect to a current path through the resistance elements.

3. The voltage generation circuit according to claim 1, wherein the diode is disposed in an opposite direction to a current path through the resistance elements.

4. The voltage generation circuit according to claim 1, wherein the variable resistor further includes a plurality of additional diodes, and a total number of the diodes is the same as a total number of the plurality of switching elements.

5. The voltage generation circuit according to claim 1, wherein the variable resistor further includes a plurality of additional diodes respectively connected in parallel to a different one of the resistance elements, and all of the diodes are connected in series to each other.

6. The voltage generation circuit according to claim 1, wherein the plurality of resistance elements include
a first resistance element to which the diode is connected in parallel, and
a second resistance element to which a diode is not connected in parallel, and
the first resistance element is disposed on a higher voltage side than the second resistance element.

7. The voltage generation circuit according to claim 1, wherein the resistance elements are each a three-terminal diffused resistance element.

8. The voltage generation circuit according to claim 1, wherein the voltage adjustment circuit includes:
a charge pump circuit configured to boost an input power supply voltage; and
a voltage difference generation circuit that is connected between an output of the charge pump circuit and the voltage output line to generate an output voltage at the voltage output line that is less than a boosted voltage output from the charge pump circuit.

9. The voltage generation circuit according to claim 8, wherein the detection circuit includes a comparator circuit configured to compare the voltage at the first connection point with a reference voltage and output a control signal for turning the charge pump circuit on and off based on a result of comparing the voltage at the first connection point with the reference voltage.

10. A semiconductor memory device comprising:
a plurality of memory cell transistors that are connected in series;
word lines connected to gates of the memory cell transistors; and
a voltage generation circuit configured to generate voltages to be supplied to the word lines, wherein the voltage generation circuit includes
a variable resistor that is connected to the word lines via a voltage output line,
a reference resistor that is connected in series to a low-voltage side of the variable resistor,
a detection circuit configured to detect a voltage at a first connection point between the variable resistor and the reference resistor, and
a voltage adjustment circuit configured to adjust a voltage at the voltage output line, based on the voltage detected by the detection circuit, and
the variable resistor includes
a plurality of resistance elements that are connected in series between the voltage output line and the first connection point,
a plurality of switching elements that are respectively provided between second connection points, each of which is located between a different adjacent pair of the resistance elements, and the first connection point, and
a diode that is connected in parallel to at least one of the plurality of resistance elements.

11. The semiconductor memory device according to claim 10, wherein the diode is disposed in a forward direction with respect to a current path through the resistance elements.

12. The semiconductor memory device according to claim 10, wherein the diode is disposed in an opposite direction to a current path through the resistance elements.

13. The semiconductor memory device according to claim 10, wherein the variable resistor further includes a plurality of additional diodes, and a total number of the diodes is the same as a total number of the plurality of switching elements.

14. The semiconductor memory device according to claim 10, wherein the variable resistor further includes a plurality of additional diodes respectively connected in parallel to a different one of the resistance elements, and all of the diodes are connected in series to each other.

15. The semiconductor memory device according to claim 10, wherein the plurality of resistance elements include
a first resistance element to which the diode is connected in parallel, and
a second resistance element to which a diode is not connected in parallel, and
the first resistance element is disposed on a higher voltage side than the second resistance element.

16. The semiconductor memory device according to claim 10, wherein the resistance elements are each a three-terminal diffused resistance element.

17. The semiconductor memory device according to claim 10, wherein the voltage adjustment circuit includes:
a charge pump circuit configured to boost an input power supply voltage; and
a voltage difference generation circuit that is connected between an output of the charge pump circuit and the voltage output line to generate an output voltage at the voltage output line that is less than a boosted voltage output from the charge pump circuit.

18. The semiconductor memory device according to claim 17, wherein the detection circuit includes a comparator circuit configured to compare the voltage at the first connection point with a reference voltage and output a control signal for turning the charge pump circuit on and off based on a result of comparing the voltage at the first connection point with the reference voltage.

19. The semiconductor memory device according to claim 10, further comprising a plurality of bit lines and a source line, wherein
the plurality of memory cell transistors are connected in series between the bit lines and the source line, and
the source line is between the plurality of memory cell transistors and the voltage generation circuit.

20. The semiconductor memory device according to claim 10, further comprising a plurality of bit lines and a source line, wherein
the plurality of memory cell transistors are connected in series between the bit lines and the source line, and
the bit lines are between the plurality of memory cell transistors and the voltage generation circuit.
